(19) United States
(12) Patent Application Publication
(10) Pub. No.: US 2022/0315802 A1
(43) Pub. Date: Oct. 6, 2022

(54) SUSPENSION FOR CHEMICAL MECHANICAL PLANARIZATION (CMP) AND METHOD EMPLOYING THE SAME

(71) Applicant: ENTEGRIS, INC., Billerica, MA (US)

(72) Inventors: Sridevi R. ALETY, Fremont, CA (US); Mark CYFFKA, El Cerrito, CA (US); Niraj MAHADEV, Milpitas, CA (US)

(21) Appl. No.: 17/708,054

(22) Filed: Mar. 30, 2022

Related U.S. Application Data
(63) Continuation of application No. 17/702,889, filed on Mar. 24, 2022.
(60) Provisional application No. 63/237,644, filed on Aug. 27, 2021.
(60) Provisional application No. 63/180,963, filed on Apr. 28, 2021.
(60) Provisional application No. 63/167,275, filed on Mar. 29, 2021.

(51) Int. Cl. C09G 1/02; H01L 21/321; C09G 1/04

(52) U.S. Cl. CPC C09G 1/02; H01L 21/3212; C09G 1/04; B82Y 40/00

(57) ABSTRACT

The present disclosure relates to aqueous suspensions suitable for chemical mechanical planarization (CMP), the use of aqueous suspensions and a method of CMP using aqueous suspensions. The suspensions and method can be used for CMP of silicon carbide surfaces.

### CROSS-REFERENCE TO RELATED APPLICATIONS

The present application is a continuation of U.S. patent application Ser. No. 17/702,889, filed Mar. 24, 2022, which claims priority to and benefit of U.S. Provisional Patent Application No. 63/167,275, filed Mar. 29, 2021, and entitled “SUSPENSION FOR CHEMICAL MECHANICAL PLANARIZATION (CMP) AND METHOD EMPLOYING THE SAME,” the entirety of which is herein incorporated by reference. The present application claims priority to and benefit of U.S. Provisional Patent Application No. 63/180,963, filed Apr. 28, 2021, and entitled “SUSPENSION FOR CHEMICAL MECHANICAL PLANARIZATION (CMP) AND METHOD EMPLOYING THE SAME,” the entirety of which is herein incorporated by reference. The present application claims priority to and benefit of U.S. Provisional Patent Application No. 63/237,644, filed Aug. 27, 2021, and entitled “SUSPENSION FOR CHEMICAL MECHANICAL PLANARIZATION (CMP) AND METHOD EMPLOYING THE SAME,” the entirety of which is herein incorporated by reference.

### FIELD

The present disclosure relates to aqueous suspensions suitable for chemical mechanical planarization (CMP), the use of aqueous suspensions and a method of CMP using aqueous suspensions.

### BACKGROUND

The CMP method is a polishing method that has both a chemical action and a mechanical action.

### SUMMARY

The aqueous suspension and any embodiments thereof, as described herein, are denoted as suspensions according to the present disclosure. It is also denoted as chemical mechanical planarization slurry of the present disclosure or “CMP slurry of the present disclosure”. Some of the slurry's ingredients act chemically, e.g., by oxidizing the surface of the substrate to be polished, thus allowing the mechanical acting, e.g., abrasive ingredients of the slurry, to remove any unevenness more gently from the substrate surfaces.

Further object of the present disclosure includes the use of the suspensions as a polishing composition, particularly suitable for polishing of silicon carbide surfaces in a chemical mechanical planarization method.

Yet another object of the present disclosure is to provide a method of chemical mechanical planarization a substrate, the method including contacting a substrate with an aqueous suspension according to the present disclosure, moving the aqueous suspension by means of a polishing pad relative to the substrate, and abrading at least a portion of the substrate to polish the substrate.

The rate of material removal can be accelerated when using the suspension in a CMP method and that simultaneously interfacial temperatures can be decreased during polishing. Further, process times can be lowered, die yields of the wafers can be increased and surface defects and scratches can be minimized. Due to constituents of one or more kinds of calcined alumina particles, one or more metal salts of chloric acid, and one or more metal salts of perchloric acid, material removal rates can be further increased up to 25-30% in comparison to an aqueous suspension only containing constituents of one or more metal salts of permanganic acid, one or more kinds of zirconia nanoparticles, one or more kinds of alumina nanoparticles, one or more salts of nitric acid, but not one or more kinds of calcined alumina particles, one or more metal salts of chloric acid, and one or more metal salts of perchloric acid, even at lower interfacial temperatures. Removal rates of >13μ/hr on single crystal 4H n-type SiC (Si-face) and >30μ/hr on C-face could be observed, while generating defect free sub angstrom substrates with high process yield. In addition, friction and motor-load in temperature-limited CMP operations can be substantially reduced and that a corresponding CMP method allows margin for process engineers to develop more aggressive process recipes that increase wafer throughput. Further, no “settling out” of any of the constituents of the suspension can be observed during product usage or while in storage conditions, and that the suspension thus has a long shelf-life, even in its acidic medium. Moreover, the constituents of the suspension adhere to the wafer surface based on various surface charge dynamics, which ensures uniform distribution of the suspension across the wafer surface. Finally, little to no amount of residues can be observed on the CMP pad after the cleaning process in between runs, by which the pad life can be increased.

In some embodiments, the present disclosure includes an aqueous suspension including (a) one or more metal salts of permanganic acid, (b) zirconia nanoparticles, (c) alumina nanoparticles, and (d) one or more salts of nitric acid.

In some embodiments, the present disclosure includes a method for preparing an aqueous suspension including (i) adding aluminum nitrate to the aqueous suspension comprising alumina nanoparticles and zirconia nanoparticles, and (ii) adding an aqueous solution of one or more metal salts of permanganic acid to the aqueous suspension.

In some embodiments, the present disclosure includes a method including storing an aqueous suspension having a pH ranging from 3 to 5, reducing the pH of the aqueous suspension to range from 2 to 2.5, and using the aqueous suspension having the pH ranging from 2 to 2.5 within fourteen days.

In some embodiments, the present disclosure includes an aqueous suspension including (a) one or more metal salts of permanganic acid, (b) one or more kinds of zirconia nanoparticles, (c) one or more kinds of alumina nanoparticles, (d) one or more salts of nitric acid, (e) one or more kinds of calcined alumina particles, (f) one or more metal salts of chloric acid, and (g) one or more metal salts of perchloric acid.

In some embodiments, the present disclosure includes a method for preparing an aqueous suspension, including (i) adding aluminum nitrate to the aqueous suspension comprising alumina nanoparticles and zirconia nanoparticles, (ii) adding an aqueous solution of one or more metal salts of permanganic acid, one or more metal salts of perchloric acid, and one or more metal salts of chloric acid to the aqueous suspension, and (iii) adding one or more kinds of calcined alumina particles to the aqueous suspension.

In some embodiments, the present disclosure includes an aqueous suspension including at least one oxidizing agent, a total amount of less than 0.2 wt.-% of abrasive particles based on a total weight of the aqueous suspension, wherein the abrasive particles have a Mohs hardness of less than 6, and aluminum nitrate.

In some embodiments, the present disclosure includes a method for preparing an aqueous suspension, including (i) adding aluminum nitrate to the aqueous suspension comprising abrasive particles; and (ii) adding an aqueous solution of at least one oxidizing agent to the aqueous suspension, wherein the abrasive particles have a Mohs hardness of less than 6, and wherein the aqueous suspension contains less than 0.2 wt.-% of the abrasive particles based on a total weight of the aqueous suspension.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

All prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

The proportions and amounts in wt.-% (% by weight) of any of the constituents given hereinafter, which are present in the aqueous suspension, add up to 100 wt.-%, based in each case on the total weight of the suspension.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “between” does not necessarily require being disposed directly next to other elements. Generally, this term means a configuration where something is sandwiched by two or more other things. At the same time, the term “between” can describe something that is directly next to two opposing things. Accordingly, in any one or more of the embodiments disclosed herein, a particular structural component being disposed between two other structural elements can be:
disposed directly between both of the two other structural elements such that the particular structural component is in direct contact with both of the two other structural elements;
disposed directly next to only one of the two other structural elements such that the particular structural component is in direct contact with only one of the two other structural elements;
disposed indirectly next to only one of the two other structural elements such that the particular structural component is not in direct contact with only one of the two other structural elements, and there is another element which juxtaposes the particular structural component and the one of the two other structural elements; disposed indirectly between both of the two other structural elements such that the particular structural component is not in direct contact with both of the two other structural elements, and other features can be disposed therebetween; or any combination(s) thereof.

As used herein “embedded” means that a first material is distributed throughout a second material.

As used herein, the grammatical articles “a”, “an”, and “the” are intended to include “at least one” or “one or more”, unless otherwise indicated, even if “at least one” or “one or more” is expressly used in certain instances. Thus, these articles are used in this specification to refer to one or more than one (i.e., to “at least one”) of the grammatical objects of the article. By way of example, and without limitation, “a component” means one or more components, and thus, possibly, more than one component is contemplated and may be employed or used in an implementation of the described embodiments. Further, the use of a singular noun includes the plural, and the use of a plural noun includes the singular, unless the context of the usage requires otherwise.

As used herein, the terms “comprises”, “comprising”, “includes”, “including”, “has”, “having” or any other variation thereof, are intended to cover a non-exclusive inclusion. For example, a composition or method that comprises a list of features is not necessarily limited only to those features but may include other features not expressly listed or inherent to such composition or method.

As used herein, and unless expressly stated to the contrary, “or” refers to an inclusive-or and not to an exclusive- or. For example, a condition A or B is satisfied by any one of the following: A is true (or present) and B is false (or not present), A is false (or not present) and B is true (or present), and both A and B are true (or present).

The term “nanoparticles” as used herein in the context with zirconia and alumina denotes for particles having a Z-average particle size in the range from 1 nm to 1000 nm, as determined via dynamic light scattering (DLS) also referred to as quasi-elastic light scattering (QELS). The Z-average particle size is also referred to as the scattered light intensity-weighted harmonic mean particle diameter which yields from the data analysis algorithm known as cumulants method. The Z-average particle size can be determined according to ISO 22412:2017(en), e.g., by use a Malvern Zetasizer Nano (Malvern Instruments Ltd., Malvern, UK).

The term “suspension” refers to a heterogeneous mixture in which the solute particles do not dissolve, but get suspended throughout the bulk of the solvent, left floating around freely in the medium.

As used herein, the term “aqueous suspension” refers to a suspension in which the main fraction of the liquid carrier of the suspension is water, i.e., the water fraction of the suspension is at least 80 wt.-%, at least 85 wt.-%, at least 90 wt.-%, or at least 92, 93, or 94 wt.-%, based in each case on the total amount of the solvents present (that is, water and organic solvents if any). In some embodiments, the water fraction of the aqueous suspension is 40 to 100 wt.-%, 60 to 100 wt.-%, or 80 to 100 wt.-%, based in each case on the total amount of the solvents present. The water being employed in the suspensions of the present disclosure can be deionized water. In some embodiments, the aqueous suspensions of the present disclosure do not contain any organic solvents, i.e., the total amount of organic solvents is 0 wt.-%, based on the total amount of solvents present.

As used herein, the term “oxidation agent” is a compound which dissolves in the aqueous carrier of the suspension and has a suitable oxidation potential for chemically reacting with a surface of a substrate. In some embodiments, the oxidizing agent has an oxidation potential of at least 0.26 V, or at least 0.4 V, or at least 0.5 V, or at least 1.0 V, or at least 1.5 V. In some embodiments, the oxidation potential may be not greater than 2.8 V, or not greater than 2.5 V, or not greater than 2.0 V. The oxidation potential is the value measured relative to the standard hydrogen electrode at a temperature of 25° C., a pressure of 1 atm, at a concentration of 1 mol/L of the tested oxidation agent in water and measured in Volt (V).

The “Mohs hardness” refers to a qualitative ordinal scale ranging from 1 to 10 and characterizing scratch resistance of various minerals through the ability of harder material to scratch softer material. As the hardest known naturally occurring substance when the scale was designed, diamonds are at the top of the scale having a Mohs hardness of 10. The hardness of a material is measured against the scale by finding the hardest material that the given material can scratch, or the softest material that can scratch the given material. “Scratching” a material for the purposes of the Mohs scale means creating non-elastic dislocations visible to the naked eye. Frequently, materials that are lower on the Mohs scale can create microscopic, non-elastic dislocations on materials that have a higher Mohs number. While these microscopic dislocations are permanent and sometimes detrimental to the harder material's structural integrity, they are not considered “scratches” for the determination of a Mohs scale number.

Over the past several decades, improvements in the cost, performance and efficiency of electric power generation, storage, and distribution systems, in conjunction with government subsidies encouraging widespread societal electrification, have accelerated the adoption of electric vehicles (EVs) and a host of other clean technologies.

The transition to a more electrified world has created demand for a new electrical infrastructure of nodes and switches to regulate the flow of electric power. At the core of this new infrastructure are power devices—solid-state transistors, similar in dimension and appearance to the computer chips powering computers and phones, but with the capability to handle large voltages and currents, and the functionality to manage the flow of electricity between, for instance, the motor and battery in an electric vehicle, or a solar cell and a battery in a home charging system.

A new generation of power devices composed of silicon carbide (SiC) has been demonstrated to dramatically outperform older, conventional silicon-based devices. Individual SiC power devices, a few mm in size, are fabricated on SiC wafers—thinly-sliced, uniform substrates of crystalline SiC, which can be 4″ or 6″ in diameter.

SiC is a material which can exist in different crystal structures known as polytypes. The crystalline stacking sequence of Si and C atoms which characterizes each polytype also determines its fundamental electrical properties. Although SiC has over 200 known polytypes, a few are commercially available, namely 3C—SiC, 4H—SiC, and 6H—SiC. Currently, 4H—SiC is widely used SiC polytype for power device production, due to its superior electrical properties. These properties enable power devices with high breakdown voltages, high power densities, high switching frequencies, improved thermal conductivity, and improved overall device efficiencies. Beyond their use in EV motor control systems & charging stations, 4H—SiC power devices have enabled improved performance in 5G wireless networks, military radar, satellite communications, power inverters for renewable electricity sources, and drones, while at the same time making these devices smaller, lighter, and more robust to environmental conditions like vibration and radiation.

Compared with silicon (Si), silicon carbide (SiC) and more particular 4H—SiC has properties which include an insulation breakdown electric field that is an order of magnitude greater, an energy band gap that is almost 3 times greater and a thermal conductivity that is almost 4 times higher, and therefore holds considerable promise for applications to power devices, high-frequency devices, and high-temperature operation devices and the like. As a result, SiC substrates are increasingly being used as substrates of semiconductor devices.

The SiC substrates described above are produced, for example, from bulk single crystal ingots of SiC prepared by a highly controlled sublimation method or the like. Usually, the outer periphery of the ingot is ground and processed into a cylindrical shape, a diamond-embedded wire saw or the like is then used to slice the cylindrical shape into circular discs, and the external periphery is then chamfered to a prescribed diameter to obtain the substrate. The diamond saw introduces large mm-sized gouges and scratches into the wafer surfaces which are removed by various stages of surface lapping and grinding processes to remove unevenness and achieve parallelism of the surfaces. However, lapping and grinding processes rely on micron-sized diamond particles, which can leave behind micron-sized surface damage in the form of scratches, pits, and gouges.

Subsequently, one surface or both surfaces of the substrate are provided with a mirror finish by subjecting the surface(s) to chemical mechanical polishing also referred to as CMP (Chemical Mechanical Planarization). This type of grinding and polishing of the SiC substrate is performed for purposes such as removing undulations and process distortions, and planarizing the surface of the SiC substrate yielding a nearly atomically-flat surface virtually free of surface defects, which is suitable for downstream epitaxy and further semiconductor fabrication processes.

The CMP method is a polishing method that has both a chemical action and a mechanical action, and therefore a planar surface can be obtained in a stable manner, without damaging the SiC substrate. As a result, CMP methods are widely employed in production processes for SiC semiconductor devices and the like, as a method for planarizing either roughness or undulations that have been generated on the surface of the SiC substrate, or planarizing unevenness due to wiring or the like.

In a CMP process, the wafer surface is pressed with controlled force against a polishing pad and rotated at controlled rotational speeds, pressures, and durations, in the presence of a CMP slurry. Polishing pads can be made from a soft, porous polymer, which provide a mechanical surface to rub against the substrate surface, as well as grooves and pores which can facilitate the flow of slurry and capture removed debris, which is oxidized surface material removed as part of the CMP process. CMP slurries can be complex liquid suspensions including oxidizers, additives, and particles, and are usually acidic or alkaline depending on the nature of the application. In the CMP process, the chemical attack of the slurry (oxidizing agents, additives, and pH) is complemented by mechanical (frictional) forces created by contact between the pad, particles, and substrate. Given the large number of chemical and mechanical process variables, developing CMP slurries requires an in-depth understanding of the process and the interactions between pad and particles, particles and wafer, and wafer and pad. For instance, the CMP processes for different materials like Si, SiC, sapphire, GaN, InP, etc., all require specific processing conditions, parameters, and consumables, unique to the technical and application requirements for each substrate.

On the one hand, in the case of SiC wafers, particularly 4H—SiC wafers, the mechanical hardness and chemical inertness demands highly aggressive CMP conditions, i.e., an aggressive CMP suspension/slurry, and aggressive CMP parameters (high pressures, fast polishing speeds, etc.) to remove SiC effectively. On the other hand, these aggressive conditions can introduce surface scratching, pitting, debris, and sub-surface damage.

Therefore, there is a need to provide CMP slurries, which are well balanced, thus avoiding damage to the substrate, but being aggressive enough to yield SiC wafers in the CMP process, having an atomically flat surface, to the point that the vicinal crystal structure can be identified via atomic force microscopy.

Furthermore, there are a variety of different CMP process approaches. In one configuration, multiple SiC wafers are processed at once in a large polishing tool. This is called a “batch-type process” and demands an especially large CMP tool, which uses a platen several feet in diameter, and is capable of processing up to more than twenty wafers at once. While batch processing creates some throughput advantages, the large number of wafers and large tool size make the process complex to tune, and prone to throughput issues. For example, if the wafers loaded into a batch-type CMP tool are not the same thickness, thicker wafers will protrude into the polishing pad and thus experience higher forces, and meanwhile thinner wafers will receive lower forces, and may even slip out during processing. This can result in unevenly-polished SiC wafers. And if one wafer in a batch process breaks into pieces under the intense mechanical forces, commonplace to CMP, wafer debris from the broken wafer can cause further scratches or breaks the entire batch of wafers. Moreover, with larger platen sizes creating a large surface area, it is difficult to for the tools to uniformly apply the extreme downward forces needed for satisfactory material removal rates; longer run times are therefore needed. Longer run times can mean the wafer is exposed to aggressive conditions for longer, thereby increasing the risk of introducing defects, scratches and significant surface damage. This has driven testing and adoption of new toolsets, pads, and slurries designed specifically for batch-type processes.

In some configurations, to overcome these defectivity and throughput challenges, SiC industry had begun transitioning from largely batch processes to single-wafer processes. In a single-wafer process, smaller platen sizes allow for higher process pressures and more uniform pressure distribution. With higher pressure comes faster material removal rates, and therefore shorter run times. Moreover, in the single-wafer process, any defective or broken wafers can be isolated without damaging other wafers. This transition to single-wafer CMP has driven testing and adoption of new toolsets, pads, and slurries designed specifically for single-wafer processes.

Due to the different process conditions, such as toolsets, polishing pads, down pressures, etc., used during batch-type and single-type CMP processes, slurries are normally designed specifically for one type of CMP process. An CMP slurry, however, can be suitable for both, the use in a batch-type CMP process and in a single wafer CMP process, alike.

Therefore, to solve the various problems of the prior art, the present disclosure provides a suspension which has a stable pH, i.e., the pH drift is less than 0.1 over a period of at least 12 months, and allows a high material removal rate while providing a low surface roughness of the polished substrate when used in batch-type CMP or single-wafer CMP processes. The present disclosure provides a suspension suitable as a CMP slurry in batch-type CMP processes as well as in single-wafer CMP processes, allowing to speed up the processes, i.e., to allow a higher throughput by significantly increasing the material removal rate. This may need a suspension being aggressive enough to polish and planarize wafers even made of 4H—SiC, while simultaneously avoiding scratches or other damages to the wafer surface. To ensure this, the suspensions can be effective as CMP slurries at lower temperatures at the interface between the polishing pad and the wafer compared to the state-of-the-art slurries. The suspensions are storage stable and sediments, e.g., any sediments, that may be formed during storage are readily re-dispersible by simple agitation such as stirring or shaking the suspension.

An aim of the present disclosure is to provide a use of such suspensions in a method of polishing, particularly of chemical mechanical planarization of wafers.

A further aim of the present disclosure is to provide an accordingly improved gentle method of chemical mechanical planarization of wafers, more particularly SiC wafers such as 4H—SiC wafers, making use of such CMP slurry.

In some embodiments, the present disclosure is an aqueous suspension having a pH value in the range from 2 to 5 and including: (a) one or more metal salts of permanganic acid; (b) zirconia nanoparticles; (c) alumina nanoparticles; and (d) one or more salts of nitric acid. In some embodiments, the present disclosure optionally includes one or more agents selected from the group of pH adjusting agents and pH buffering agents. In some embodiments, the pH value is measured from a temperature range of 20° C. to 30° C., e.g., 23° C. In some embodiments, the aqueous suspension contains particles having a Mohs hardness of more than 1, more than 2, more than 3 and more than 4.

In some embodiments, the present disclosure is an aqueous suspension including (a) one or more metal salts of permanganic acid; (b) one or more kinds of zirconia nanoparticles; (c) one or more kinds of alumina nanoparticles; (d) one or more salts of nitric acid; (e) one or more kinds of calcined alumina particles; (f) one or more metal salts of chloric acid; and (g) one or more metal salts of perchloric acid. In some embodiments, the present disclosure optionally includes one or more agents selected from the group of pH adjusting agents and pH buffering agents. In some embodiments, the aqueous suspension has a pH value in a range from 2 to 5. In some embodiments, the pH value of the aqueous suspension is measured from a temperature range of 15° C. to 40° C., e.g., 23° C. In some embodiments, the aqueous suspension contains particles having a Mohs hardness of more than 1, more than 2, more than 3 and more than 4.

In some embodiments, the present disclosure is an aqueous suspension having a pH value at 23° C. of 2 to 5 and including at least one oxidizing agent, a total amount of less than 0.2 wt.-% of abrasive particles, aluminum nitrate. In some embodiments, the present disclosure optionally includes one or more agents selected from the group of pH adjusting agents and pH buffering agents. In some embodiments, all abrasive particles present in the aqueous suspension have a Mohs hardness of less than 6 to avoid scratching of the surface of the substrate during the polishing process. In some embodiments, the pH value is measured from a temperature range of 15° C. to 40° C., e.g., 23° C. In some embodiments, the present disclosure includes providing an aqueous suspension having a pH value at 23° C. of 2 to 5 and comprising—based on the total weight of the aqueous suspension—at least one oxidizing agent, a total amount of less than 0.2 wt.-% of abrasive particles; aluminum nitrate; and optionally at least one pH adjusting agent and/or at least one pH buffering agent, wherein all abrasive particles present in the aqueous suspension have a Mohs hardness of less than 6. In some embodiments, the present disclosure includes a method for preparing an aqueous suspension (AS) having a pH value at 23° C. of 2 to 5, comprising providing an aqueous suspension of abrasive particles (ASP), wherein all abrasive particles present in the aqueous suspension have a Mohs hardness of less than 6, adding aluminum nitrate to the aqueous suspension (ASP) provided in the step of providing an aqueous suspension, adding an aqueous solution of at least one oxidizing agent to the aqueous suspension obtained after the step of adding aluminum nitrate, and optionally adjusting the pH of the aqueous suspension resulting after the step of adding an aqueous solution with at least one pH adjusting agent, wherein the aqueous suspension (AS) resulting from the method contains less than 0.2 wt.-%, based on the total weight of the aqueous suspension, of abrasive particles

The at least one oxidizing agent can be any suitable oxidation agent that oxidizes the chemical bonds, such as the Si—C bonds, on the surface of the substrate, such as the silicon carbide substrate, to be polished.

Suitable oxidizing agents include persulfates, organic peroxides, inorganic peroxides, peroxyacids, permanganates, chromates, percarbonates, chlorates, bromates, iodates, perchloric acid and salts thereof, perbromic acid and salts thereof, periodic acid and salts thereof, hydroxylamine and salts thereof, ferricyanide, oxone, and combinations thereof.

In some embodiments, the at least one oxidizing agent is a metal salt of permanganic acid, e.g., an alkali metal salt of permanganic acid. Alkali metal salts of permanganic acid can be selected from lithium permanganate, potassium permanganate, sodium permanganate and mixtures thereof, e.g., of potassium permanganate.

In some embodiments, the at least one oxidizing agent is potassium permanganate.

In some embodiments, the at least one oxidizing agent may be present in a total amount of 0.1 to 10 wt.-%, 1 to 8 wt.-%, 2 to 6 wt.-%, 3 to 5.5 wt.-%, or 4 to 5 wt.-%, based in each case on the total weight of the aqueous suspension. In some embodiments, the afore-mentioned ranges apply irrespective if only one type of oxidizing agent is employed in the suspension according to the present disclosure or a mixture of different oxidizing agents is employed. In some embodiments, if, e.g., the potassium permanganate is employed as the only oxidizing agent, the afore-mentioned ranges apply to potassium permanganate.

If the amount of the at least one oxidizing agent is too low, the material removal rate of the suspension in a CMP method can also be too low; and if the amount of the at least one oxidizing agent is too high, the oxidation power is can be too strong, thus creating surface defects primarily due to an etching-like mechanism. The balance of properties and efficiency in a CMP method is can be achieved, if the amount of the at least one oxidizing agent is 0.1 to 10 wt.-% or 3 to 5.5 wt.-% or 4 to 5 wt.-%, based in each case on the total weight of the aqueous suspension.

In some embodiments, all abrasive particles present in the suspension of the present disclosure have a Mohs hardness of less than 6. Use of abrasive particles having a Mohs hardness of less than 6 (i.e., “soft” abrasive particles) results in the formation of an aqueous suspension which is storage stable and thus shows constant quality during its shelf-life while the use of abrasive particles having a Mohs hardness of higher than 6, e.g., alumina particles having a Mohs hardness of higher than 6, resulted in the formation of unstable suspensions. Moreover, the use of aqueous suspensions including these “soft” abrasive particles surprisingly results in higher material removal rates, lower polishing temperatures and lower surface roughness (i.e., higher quality of the polished substrate) in batch-type and single-type CMP processes as compared to the use of aqueous slurries including abrasive particles having a Mohs hardness of more than 6, such as silica.

In some embodiments, the abrasive particles have a Z-average particle size of 1 nm to 1000 nm, 10 to 500 nm, 20 to 300 nm, 50 to 200 nm, or 75 to 150 nm. Thus, the abrasive particles can be abrasive nanoparticles. The Z-average particle size is also referred to as the scattered light intensity-weighted harmonic mean particle diameter which yields from the data analysis algorithm known as cumulants method. The Z-average particle size can be determined according to ISO 22412:2017(en), e.g., by use a Malvern Zetasizer Nano (Malvern Instruments Ltd., Malvern, UK).

In some embodiments, the abrasive particles have a Mohs hardness of less than 5.5, less than 5, or 3 to 4. The abrasive particles can include (e.g., comprise, consist essentially of, or consist of) one or more metal oxides having the aforementioned Mohs hardness of less than 6, e.g., Mohs hardness of 3 to 4. The metal oxide can be selected from metal oxides of alumina, titania, zirconia, ceria, germania, magnesia, and combinations thereof which have a Mohs hardness of less than 6. The aqueous suspensions may contain only one type of abrasive particles or may contain a mixture of different types abrasive particle.

In some embodiments, the abrasive particles can include (e.g., comprise, consist essentially of, or consist of) of alumina particles having a Mohs hardness of less than 6. In some embodiments, alumina particles in the sense of the present disclosure are particles containing at least one of an aluminum oxide such as an aluminum hydroxide, an aluminum oxide hydroxide, a hydrate of any of the aforementioned alumina species, and mixed metal species including and being composed of any of the aforementioned alumina species and at least one further metal atom and/or oxide and/or hydroxide thereof, and/or metal ion and having a Mohs hardness of less than 6. In some embodiments, the alumina particles can include (e.g., comprise, consist essentially of, or consist of) at least one of an aluminum hydroxide, an aluminum oxide hydroxide or a hydrate of any of the aforementioned alumina species.

The alumina particles may be present in a colloidal form or in an amorphous form such as a polycrystalline amorphous form. In some embodiments, the abrasive particles can include (e.g., comprise, consist essentially of, or consist of) boehmite (denoted γ-AlOOH hereinafter) particles and/or γ-Al₂O₃ particles, and can be in colloidal form. For example, the aqueous suspension can include colloidal alumina particles of γ-AlOOH particles and/or γ-Al₂O₃ particles. In some embodiments, the aqueous suspension includes—apart from the alumina particles having a Mohs hardness of less than 6, e.g., γ-AlOOH particles—0 wt.-%, based on the total weight of the aqueous suspension, of further abrasive particles. The use of boehmite as single abrasive results—in combination with aluminum nitrate—in a better stability of the aqueous suspensions while the use of other alumina, such as alpha-alumina, or the use of other nitrates, such as ferric nitrate, cerium nitrate and manganese nitrate, results in reduced storage stability of the aqueous suspensions due to the formation of an instable suspension or the formation of undesired reaction products. Moreover, the use of boehmite as single abrasive results in less scratching of the surface of the substrate during the polishing process and a lower polishing temperature for a given down pressure, thus allowing to improve the surface quality and reduce the substrate damage and therefore to improve the quality (or yield) of the CMP process.

In some embodiments, the suspension according to the present disclosure contains a total amount of less than 0.2 wt.-%, 0.15 wt.-%, 0.1 wt.-%, or 0.05 wt.-% of abrasive particles. This listing of ranges is not exhaustive and includes any intervening numbers, e.g., less than 0.13 wt.-%. In some embodiments, the suspension according to the present disclosure contains a total amount of abrasive particles ranging from 0.005 wt.-% to 0.2 wt.-%, from 0.005 wt.-% to 0.15 wt.-%, from 0.005 wt.-% to 0.1 wt.-%, or from 0.005 wt.-% to 0.05 wt.-%, from 0.005 wt.-% to 0.01 wt.-%, from 0.01 wt.-% to 0.2 wt.-%, from 0.05 wt.-% to 0.2 wt.-%, from 0.1 wt.-% to 0.2 wt.-%, from 0.15 wt.-% to 0.2 wt.-%, from 0.05 wt.-% to 0.15 wt.-%, from 0.01 wt.-% to 0.15 wt.-%, or from 0.05 wt.-% to 0.1 wt.-%. This listing of ranges is not exhaustive and includes any intervening numbers, e.g., from 0.07 wt.-% to 0.13 wt.-%.

The alumina particles can be produced by any known method in the field of the art.

In some embodiments, the suspension according to the present disclosure contains a total amount of less than 0.2 wt.-% of abrasive particles, and in some embodiments less than 0.2 wt.-% of γ-AlOOH particles, based on the total weight of the suspension. Use of less than 0.2 wt.-% of abrasive particles, e.g., γ-AlOOH particles, surprisingly results in acceptable material removal rates in batch-type CMP processes but provides polished substrates having a significantly lower surface roughness as compared to the use of higher amounts of abrasive particles. Additionally, the use of lower amounts of said alumina particles allows to obtain aqueous suspensions which are highly storage stable, i.e., a change in pH upon storage of more than 12 month is 0.1 or less, thus preventing, reducing, or restricting the formation of undesired reaction products which result in reduced material removal rates and increased surface roughness during the polishing process. Moreover, the use of these low amounts of abrasive particles avoids clogging of slurry distribution lines or filling of the polishing pad's pores such that the polishing pad becomes too smooth, resulting in a significant drop of the material removal rate.

In some embodiments, the abrasive particles, e.g., γ-AlOOH particles, are present in a total amount of less than 0.18 wt.-%, less than 0.15 wt.-%, or less than 0.12 wt.-%, based in each case on the total weight of the aqueous suspension. For example, the total amount of abrasive particles, e.g., γ-AlOOH particles, can be 0.001 to 0.18 wt.-%, 0.01 to 0.15 wt.-%, or 0.08 to 0.12 wt.-%, based in each case on the total weight of the aqueous suspension.

In some embodiments, the aqueous suspensions of the present disclosure contain aluminum nitrate. The use of aluminum nitrate allows to avoid a pH drift, i.e., the pH of the aqueous suspensions of the present disclosure does change less than 0.1 upon storage of these suspensions for at least 12 months. Since material removal rates during CMP are observed to be a function of the pH of the polishing suspension, the stable pH of the aqueous suspensions during the shelf-life of the polishing suspension allows uniform material removal rates. Moreover, the stable pH of the aqueous suspensions avoids the formation of undesired reaction products, such as manganese dioxide, which are formed upon a pH drift to higher pH values, because these reaction products result in reduce material removal rates as well as an increased surface roughness of the substrate, thus reducing the yield achieved with the aqueous suspensions after storage. Moreover, without wishing to be bound to this theory, it is believed that the aluminum nitrate forms a soft network embedding the abrasive particles, thus forming a “soft” layer on the particle surface which results in improved surface roughness and reduced surface defects during polishing. Surprisingly, the formation of the “soft” layer on the abrasive particles does, however, not result in a reduced material removal rate. The aqueous suspensions therefore have a high material removal rate and provide polished substrates in an excellent yield, i.e., having a low surface roughness or a low amount of surface defects, during their whole shelf-life.

In some embodiments, the aluminum nitrate is present in a total amount of 0.05 to 3 wt.-%, of 0.1 to 2 wt.-%, of 0.2 to 1.5 wt.-%, or of 0.3 to 1 wt.-%, based in each case on the total weight of the aqueous suspensions. If the amount of aluminum nitrate is too low, an undesired pH drift of the aqueous suspension upon storage time is observed, while high amounts of aluminum nitrate result in defects, such as pitting, on the substrate surface and an undesired increase in the substrate/pad interfacial temperature. Thus, in some embodiments, the aqueous suspensions of the present disclosure contain the aluminum nitrate in the aforementioned amounts. This allows to achieve a stable pH of the aqueous suspension during storage time as well as high yield without negatively influencing the material removal rates.

In some embodiments, the present disclosure is an aqueous suspension having a pH value in the range from 2.0 to 5.0 and including one or more alkali metal permanganate salts, zirconia nanoparticles, alumina nanoparticles, one or more salts of nitric acid and optionally a pH adjusting agent and/or a pH buffering agent. In some embodiments, the suspension in conjunction with a polishing pad can be an important component of the chemical mechanical planarization method claimed in the present disclosure. It is also denoted as chemical mechanical planarization slurry or “CMP slurry”. Some of the slurry's ingredients act chemically, e.g., by oxidizing the surface of the wafers to be polished, thus allowing the mechanical acting, e.g., abrasive ingredients of the slurry to more gently remove any unevenness from the wafer surfaces.

In some embodiments, the pH of the aqueous suspension of the present disclosure ranges from about 2 to about 5, from about 2.5 to about 5, from about 3 to about 5, from about 3.5 to about 5, from about 4 to about 5, from about 4.5 to about 5, from about 2 to about 4.5, from about 2 to about 4, from about 2 to about 3.5, from about 2 to about 3, from about 2 to about 2.5, from about 2.5 to about 3.5, from about 3 to about 4.5, or any intervening value (e.g., about 4.3) or range (e.g., about 2.6 to about 4.8).

In some embodiments, the aqueous suspension includes one or more metal salts of permanganic acid as constituents(s). In some embodiments, the one or more metal salts of permanganic acid include, e.g., LiMnO₄, KMnO₄ and/or NaMnO₄.

In some embodiments, one or more metal salts of permanganic acid can be selected from alkali metal salts of permanganic acid, selected from the group consisting of lithium permanganate, sodium permanganate, potassium permanganate and mixtures thereof, or selected from the group consisting of sodium permanganate, potassium permanganate and mixtures thereof.

In some embodiments, at least two different metal salts of permanganic acid are present, selected from the group consisting of sodium permanganate and potassium permanganate, wherein the amount of sodium permanganate exceeds the amount of potassium permanganate, wherein the weight ratio of sodium permanganate to potassium permanganate is in a range of from 7:1 to 1.5:1, or in a range of from 6:1 to 1.7:1, e.g., from 5.5:1 to 1.9:1.

In some embodiments, the one or more metal salts of permanganic acid are present in an amount in a range of from 7.5 to 30 wt.-%, in a range of from 10 to 25 wt.-%, from 12 to 22 wt.-%, or from 13 to 20 wt.-%, in each case based on the total weight of the aqueous suspension. In some embodiments, at least two different metal salts of permanganic acid are present, e.g., selected from the group consisting of sodium permanganate and potassium permanganate.

The metal salt(s) of permanganic acid can serve as oxidizing agents to promote the oxidation of the SiC bonds on the surface of the wafers to be polished. In some embodiments, alkali metal permanganates such as sodium permanganate, potassium permanganate and lithium permanganate are used as oxidizing agents. However, in some embodiments, potassium permanganate is used as the permanganate.

In some embodiments, the metal salt(s) of permanganic acid is present in an amount of 2.0 to 6.0 wt.-%, 2.6 to 5.5 wt.-%, 3.0 to 5.0 wt.-%, or in a range of 4.0 to 5.0 wt.-%, such as 4.2 to 4.8 wt.-%, the amounts being based on the total weight of the suspension according to the present disclosure.

The afore-mentioned ranges apply irrespective if only one type of metal salt of permanganic acids is employed in the suspension according to the present disclosure or a mixture of metal salts of permanganic acids is employed. In some embodiments, if, e.g., the potassium permanganate is employed as the only metal salt of permanganic acid, the afore-mentioned ranges apply to potassium permanganate.

In some embodiments, if the amount of the metal salt(s) of permanganic acid is below 2.0 wt.-% the material removal rate of the suspension in the CMP method is too low; and if the amount of the metal salt(s) of permanganic acid is above 6.0 wt.-% the oxidation power is too strong, thus creating surface defects primarily due to an etching-like mechanism. A balance of properties and efficiency in the CMP method can be achieved, if the amount of the metal salt(s) of permanganic acid is in the range from 3.0 to 5.0 wt.-% or even better from 4.0 to 5.0 wt.-%. All of the afore-mentioned amounts being based on the total weight of the suspension according to the present disclosure.

In some embodiments, the aqueous suspension includes one or more kinds of zirconia nanoparticles as constituents(s). In some embodiments, the zirconia nanoparticles include ZrO₂.

Zirconia nanoparticles in the sense of the present disclosure are nanoparticles containing and composed of at least one of a zirconium oxide such as zirconium (IV) oxide, a zirconium hydroxide, a zirconium oxide hydroxide, a hydrate of any of the aforementioned zirconia species, and mixed metal species including and being composed of any of the aforementioned zirconia species and at least one further metal atom and/or oxide and/or hydroxide thereof, and/or metal ion. The zirconia nanoparticles may be present in a colloidal form. In some embodiments, the zirconia nanoparticles are nanoparticles containing and being composed of at least one zirconium oxide such as zirconium (IV) oxide.

The suspension of the present disclosure contains zirconia nanoparticles. As set out herein, zirconia nanoparticles are particles having a Z-average particle size in the range from 1 nm to 1000 nm, in the range from 10 to 500 nm, in the range from 20 to 300 nm, in the range from 50 to 200 nm and in the range from 75 to 150 nm.

The zirconia nanoparticles can be produced by any know method in the field of the art. The aforementioned patent application document describes the production of zirconia nanoparticles by using a hydrothermal process yielding a zirconia sol. The nanoparticles in such sol are aggregates of zirconia subunits and the Z-average particle size determined is the particle size of the aggregates.

The zirconia particles can be employed in the suspensions of the present disclosure in form of more concentrated colloidal compositions to achieve the desired concentrations as needed for the suspensions of the present disclosure.

The suspension according to the present disclosure contains 0.05 to 5.0 wt.-%, 0.1 to 2.0 wt.-%, 0.15 to 1.0 wt.-%, or 0.15 to 0.5 wt.-% of the zirconia nanoparticles, based on the total weight of the suspension. In some embodiments, one or more kinds of zirconia nanoparticles can be present in an amount in a range of from 0.05 to 5.0 wt.-%, from 0.10 to 4.0 wt.-%, from 0.15 to 3.0 wt.-%, from 0.15 to 2.0 wt.-%, or from 0.25 to 1.5 wt.-%, in each case based on the total weight of the aqueous suspension.

In some embodiments, if the amount of zirconia nanoparticles is too high, the solution becomes more viscous. Furthermore, the polishing pad's pores may “glaze”, filling with particles and become too smooth. Moreover, the particles may settle in solution, thereby creating clogging issues in pumped slurry distribution lines. If the amount of zirconia nanoparticles is too low, there is insufficient mechanical abrasive force, causing the material removal rate to drop to a level being too low to be useful. In some embodiments, at the ranges of the present disclosure, there is a balance of material removal rate without observable settling issues or the viscosity being too high. In some embodiments, at the ranges of both constituents one or more kinds of Metal Salt(s) of Permanganic Acid and one or more kinds of zirconia nanoparticles, there is a balance of chemical and mechanical activity in order to generate sub angstrom surface quality with low process temperature increase.

In some embodiments, the presence of zirconia nanoparticles in the suspensions of the present disclosure creates a “chemical tooth” functionality, by which zirconia nanoparticles facilitate the selective or catalytically-enhanced oxidation of the silicon-carbon bond by the metal salt of permanganic acid, e.g., by potassium permanganate.

In some embodiments, the aqueous suspension includes one or more kinds of alumina nanoparticles as constituents(s). In some embodiments, the alumina nanoparticles include colloidal alumina particles, such as γ-AlOOH particles and/or γ-Al₂O₃ particles.

Alumina nanoparticles in the sense of the present disclosure can be nanoparticles containing and composed of at least one of an aluminum oxide such as aluminum (III) oxide, an aluminum hydroxide, an aluminum oxide hydroxide, a hydrate of any of the aforementioned alumina species, and mixed metal species including, e.g., being composed of any of the aforementioned alumina species and at least one further metal atom and/or oxide and/or hydroxide thereof, and/or metal ion. The alumina nanoparticles may be present in a colloidal form or in an amorphous form such as a polycrystalline amorphous form. α-, β-, or theta-alumina powders may also be used as alumina nanoparticles. In some embodiments, the alumina nanoparticles are nanoparticles containing and being composed of at least one aluminum oxide such as aluminum (III) oxide.

The suspension of the present disclosure contains zirconia nanoparticles. As set out herein, alumina nanoparticles are particles having a Z-average particle size in the range from 1 nm to 1000 nm, in the range from 10 to 500 nm, in the range from 20 to 300 nm, in the range from 50 to 200 nm and in the range from 75 to 150 nm.

The alumina nanoparticles can be produced by any know method in the field of the art as.

The alumina particles can be employed in the suspensions of the present disclosure in form of more concentrated compositions to achieve the desired concentrations as needed for the suspensions of the present disclosure.

In some embodiments, the suspension according to the present disclosure contains 0.05 to 5.0 wt.-%, 0.1 to 2.0 wt.-%, 0.15 to 1.0 wt.-%, or 0.15 to 0.5 wt.-% of the alumina nanoparticles, based on the total weight of the suspension. In some embodiments, the one or more kinds of alumina nanoparticles can be present in an amount in a range of from 0.05 to 5.0 wt.-%, from 0.10 to 4.0 wt.-%, from 0.15 to 3.0 wt.-%, or from 0.15 to 2.0 wt.-%, in each case based on the total weight of the aqueous suspension.

If the amount of alumina nanoparticles is too high, the solution may become too viscous and the particles may settle, creating clogging issues in pumped slurry distribution lines. In such cases, a lower amount of alumina is to be chosen. If the amount of alumina nanoparticles is too low, there is insufficient mechanical abrasive force, causing the removal rate to drop too low to be useful. At the level in the ranges of the present disclosure, there is a balance of material removal without observable settling issues, the viscosity being too high and polishing pad glazing.

In some embodiments, the presence of the alumina nanoparticles allows for a decreased and thus effective CMP process temperature compared to suspensions not containing alumina nanoparticles.

In some embodiments, the aqueous suspension includes one or more one or more salts of nitric acid as constituents(s). In some embodiments, the one or more salts of nitric acid include Al(NO₃)₃.

The suspension according to the present disclosure contains 0.1 to 3.0 wt.-% of the one or more salts of nitric acid, 0.2 to 2.0 wt.-% of the one or more salts of nitric acid, or 0.5 to 1.5 wt.-% such as 0.5 to 1.0 wt.-% of the one or more salts of nitric acid. In some embodiments, salts of nitric acid (e.g., one or more salts of nitric acid) can be selected from metal nitrates.

In some embodiments, the salts of nitric acid adjust the pH value of the suspension of the present disclosure. Therefore, it is that the salts of nitric acid to be used in the present disclosure are apt to acidify the aqueous suspension of the present disclosure.

The salts of nitric acid can be diverse, but still have the desired effect. Suitable salts of nitric acid are e.g., ammonium nitrate, alkali metal nitrates, alkaline earth metal nitrates, transition metal nitrates and nitrates of IUPAC group 13 of the Periodic System of the Elements. Amongst the mentioned nitrates of the present disclosure, in some embodiments, the nitrates are metal nitrates. Examples of suitable nitrates are, e.g., calcium nitrate, magnesium nitrate, iron (III) nitrate and copper (II) nitrate. In some embodiments, the counter ion to the nitrate anion is in a high oxidation state, e.g., in case of iron in the 3+ state (i.e., as iron (III) nitrate). This is because iron (II) nitrate would immediately be oxidized by the salt of permanganic acid, thus leading to the formation of iron (III) nitrate, but diminishing the amount of the permanganate which is undesirably reduced in the same reaction.

In some embodiments, the presence of the metal cations and the nitrate counterion provide benefits in the silicon carbide oxidation.

In some embodiments, the aqueous suspension includes one or more kinds of calcined alumina particles as constituents(s). In some embodiments, the one or more kinds of calcined alumina particles comprises aluminum oxide that has been heated at temperatures in excess of 1000° C. to drive off chemically combined water.

Calcined alumina is alumina, in particular aluminum oxide such as aluminum (III) oxide, that has been heated at temperatures in excess of 1000° C. to drive off chemically combined water. This term is known by a person skilled in the art. Calcined alumina particles are present to further enhance mechanical abrasion of surfaces, e.g., chemically oxidized SiC surfaces.

In some embodiments, alpha alumina particles are used. In some embodiments, the calcined alumina particles have a particle size, which is greater than the particle size of the particles of constituents including zirconia nanoparticles and alumina nanoparticles, e.g., which is in a range of from 0.5 μm to 5 μm. The particle size in this regard is an average particle size and is determined via laser diffraction according to ISO 13320:2020-01.

In some embodiments, the one or more kinds of calcined alumina particles are present in an amount in a range of from 0.1 to 5.0 wt.-%, from 0.1 to 2.0 wt.-%, from 0.1 to 1.0 wt.-%, in each case based on the total weight of the aqueous suspension.

In some embodiments, if the amount of calcined alumina particles is too high, the particles may flocculate and make the slurry unstable. In some embodiments, if the amount of calcined alumina particles is too low, the suspension may not provide sufficient mechanical abrasion.

In some embodiments, the aqueous suspension includes one or more metal salts of chloric acid as constituents(s). In some embodiments, the one or more metal salts of chloric acid includes NaClO₃.

In some embodiments, the one or more metal salts of chloric acid are selected from alkali metal salts of chloric acid and non-transition metal salts of chloric acid, e.g., from the group consisting of lithium chlorate, sodium chlorate, potassium chlorate, aluminum chlorate and mixtures thereof, such as from the group consisting of sodium chlorate, potassium chlorate, aluminum chlorate and mixtures thereof.

In some embodiments, the one or more metal salts of chloric acid are present in an amount in a range of from 0.1 to 2.0 wt.-%, from 0.1 to 1.0 wt.-%, from 0.2 to 1.0 wt.-%, from 0.2 to 0.5 wt.-%, in each case based on the total weight of the aqueous suspension.

In some embodiments, if the amount of the one or more metal salts of chloric acid is too high, the material removal rate may decrease and the slurry may become unstable. In some embodiments, if the amount of the one or more metal salts of chloric acid is too low, the suspension may not provide a sufficient material removal rate.

The aqueous suspension comprises one or more metal salts of perchloric acid as constituents(s). In some embodiments, the one or more metal salts of perchloric acid includes Al(ClO₄)₃.

In some embodiments, the one or more metal salts of perchloric acid are selected from alkali metal salts of perchloric acid and non-transition metal salts of perchloric acid, e.g., are selected from the group consisting of lithium perchlorate, sodium perchlorate, potassium perchlorate, aluminum perchlorate and mixtures thereof, such as selected from the group consisting of sodium perchlorate, potassium perchlorate, aluminum perchlorate and mixtures thereof.

In some embodiments, the one or more metal salts of perchloric acid are present in an amount in a range of from 0.1 to 2.0 wt.-%, from 0.1 to 1.0 wt.-%, from 0.2 to 1.0 wt.-%, from 0.2 to 0.5 wt.-%, in each case based on the total weight of the aqueous suspension.

In some embodiments, if the amount of the one or more metal salts of perchloric acid is too high, the material removal rate may decrease and the slurry may become unstable. In some embodiments, if the amount of the one or more metal salts of perchloric acid is too low, the suspension may not provide a sufficient material removal rate.

The suspensions according to the present disclosure are “aqueous”. An aqueous suspension contains as its main liquid carrier medium water, e.g., deionized water. In some embodiments, based on the total weight of the suspension, the amount of water is at least 60 wt.-%, at least 65 wt.-%, at least 70 wt.-%, at least 75 wt.-%, at least 80 wt.-%, at least 85 wt.-%, at least 90 wt.-%, at least 92, 93, or 94 wt.-% and less than 97.5 wt.-%, less than 97 wt.-%, less than 96.5 wt.-% or less than 95.5 wt.-%. Even though, any of the above lower limits can be combined with any of the above higher limits, ranges of the amount of water contained in the suspension according to the present disclosure are from 60 to 97 wt.-%, 80 to 97 wt.-%, 65 to 96.5 wt.-%, 85 to 96.5 wt.-%, 70 to 96 wt.-% (such as 75 to 95.5 wt.-% or 80 to 95 wt.-%), or 90 to 96 wt.-% (such as 92 to 95.5 wt.-% or 93 to 95 wt.-% or 94 to 95 wt.-%). The water being employed in the suspensions of the present disclosure can be deionized water.

In some embodiments, the aqueous suspensions of the present disclosure have a pH value at 23° C. in the range from 2.0 to 5.0, in the range from 2.5 to 4.5, or in the range from 3.0 to 4.0, such as in the range from 3.2 to 3.8. In some embodiments, the aqueous suspensions of the present disclosure can have a pH value at 23° C. in the range from 3.0 to 5.5, from 3.5 to 5.0, or from 4.0 to 5.0. In some embodiments, the aqueous suspensions of the present disclosure have a pH value at 23° C. of 2 to 5, of 3 to 4, or of 3.4 to 4.

The pH of the suspension according to the present disclosure can be achieved and/or maintained by any suitable means. More specifically, the suspension can further include pH adjusting agents, pH buffering agents, or combinations thereof. The terms pH adjusting agents and pH buffering agents as used in this specification do not encompass the mandatory ingredients of the suspensions of the present disclosure, although the mandatory ingredients may have an influence on the pH values. Thus, the pH adjusting agents and pH buffering agents explicitly differ from the other components of the suspension of the present disclosure described under the other headlines. Thus, the pH adjusting agents and pH buffering agents also particularly differ from the salts of nitric acid as described herein.

The pH adjustor can include (e.g., comprise, consist essentially of, or consist of) any suitable pH-adjusting compound. In some embodiments, the above-mentioned nitric acid salts already serve to adjust the pH value in the desired ranges. However, in some cases it might be desired to further adjust the pH value by use of a separate pH adjustor which differs from the salts of nitric acid. For example, the pH adjustor can be any suitable acid. In some embodiments, the pH adjustor is an inorganic acid. In some embodiments, the acid is nitric acid.

The pH buffering agent, if present at all, can be any suitable buffering agent, including an inorganic pH buffering agent, as for example, phosphates, borates, and the like. In some embodiments, no pH buffering agent is present in the suspensions of the present disclosure.

The suspension according to the present disclosure can include any suitable amount of a pH adjustor and/or a pH buffering agent, provided such amount is sufficient to achieve and/or maintain the desired pH value of the suspension, e.g., within the ranges as set forth herein.

The suspensions of the present disclosure may include further optional ingredients. In some embodiments, no further ingredients are contained in the suspensions of the present disclosure. Thus, the suspensions of the present disclosure can include (e.g., consist essentially of, or consist of) one or more metal salts of permanganic acid, zirconia nanoparticles, alumina nanoparticles, one or more salts of nitric acid, water and optionally one or more of pH adjustment agents and/or pH buffering agents. Of course, undesired and unavoidable impurities, present in the afore-mentioned ingredients may be present in a suspension comprising, consisting essentially of, or consisting of the afore-mentioned ingredients. Such impurities, which are not considered herein as further optional ingredients, but as unavoidable and undesired impurities, can be contained in an amount less than 0.005 wt.-%, less than 0.002 wt.-%, or less than 0.001 wt.-%, based on the weight of the suspension of the present disclosure.

In some embodiments, the suspensions of the present disclosure may include further optional constituents (optional ingredients). In some embodiments, no further ingredients are contained in the suspensions of the present disclosure. Thus, in some embodiments, the suspensions of the present disclosure consist of (or consists essentially of) one or more metal salts of permanganic acid, one or more kinds of zirconia nanoparticles, one or more kinds of alumina nanoparticles, one or more salts of nitric acid, one or more kinds of calcined alumina particles, one or more metal salts of chloric acid, and one or more metal salts of perchloric acid, water and optionally one or more of pH adjustment agents and/or pH buffering agents.

In some embodiments, the suspensions of the present disclosure can include (e.g., comprise, consist essentially of, or consist of) at least one oxidizing agent, a total amount of less than 0.2 wt.-% of abrasive particles, aluminum nitrate, water and optionally at least one pH adjustment agent and/or at least one pH buffering agent. All abrasive particles present in the suspensions of the present disclosure have a Mohs hardness of less than 6. Of course, undesired and unavoidable impurities, present in the afore-mentioned ingredients may be present in a suspension comprising, consisting essentially of, or consisting of the afore-mentioned ingredients. Such impurities, which are not considered herein as further optional ingredients but as unavoidable and undesired impurities, can be contained in an amount less than 0.005 wt.-%, less than 0.002 wt.-%, or less than 0.001 wt.-%, based on the weight of the suspension of the present disclosure.

However, it is also possible that further ingredients are consciously added to the afore-mentioned suspensions. In some embodiments, such further ingredients may need to be inert, i.e., non-reactive with the reactive ingredients of the suspension, such as with the one or more metal salts of permanganic acid in the suspension.

Thus, in case further ingredients are contained in the suspension of the present disclosure, in some embodiments, such ingredients can be of inorganic nature, since organic compounds such as organic surfactants, organic defoamers or organic solvents would be degraded in an oxidation process by the ingredients such as the at least one oxidizer, the one or more metal salts of permanganic acid, the one or more metal salts of chloric acid, and/or one or more metal salts of perchloric acid and therefore are excluded in some embodiments from the suspensions of the present disclosure.

In some embodiments, if the further optional ingredients are present, the further ingredients can be inorganic ingredients and their amount can be from 0.005 to 1 wt.-%, 0.005 to 1.5 wt.-%, 0.005 to 1 wt.-% or 0.005 to 0.5 wt.-%, based on the weight of the suspension of the present disclosure.

In some embodiments, the aqueous suspension is absent certain components. For example, in some embodiments, the aqueous suspension is absent MnO₂, germanium particles and/or ceria particles.

In some embodiments, the sum of constituents of the aqueous suspension (e.g., salts of permanganic acid, zirconia nanoparticles, alumina nanoparticles and salts of nitric acid) makes up at least 90 wt.-%, at least 95 wt.-%, or at least 98 wt.-% of all ingredients of the suspension of the present disclosure excluding water, the pH adjusting agents and pH buffering agents. In some embodiments, the only ingredients of the suspension of the present disclosure are the one or more salts of permanganic acid, zirconia nanoparticles, alumina nanoparticles, the one or more salts of nitric acid, water, and the pH adjusting agents and pH buffering agents, thus the suspensions consist of or consist essentially of these ingredients.

In some embodiments, the sum of constituents of the aqueous suspension (e.g., the ingredients including one or more metal salts of permanganic acid, one or more kinds of zirconia nanoparticles, one or more kinds of alumina nanoparticles, one or more salts of nitric acid, one or more kinds of calcined alumina particles, one or more metal salts of chloric acid, and one or more metal salts of perchloric acid) makes up at least 90 wt.-%, at least 95 wt.-% and at least 98 wt.-% of all constituents of the suspension of the present disclosure excluding water, the pH adjusting agents and pH buffering agents. In some embodiments, the only constituents of the suspension of the present disclosure are constituents of one or more metal salts of permanganic acid, one or more kinds of zirconia nanoparticles, one or more kinds of alumina nanoparticles, one or more salts of nitric acid, one or more kinds of calcined alumina particles, one or more metal salts of chloric acid, and one or more metal salts of perchloric acid, water, and the pH adjusting agents and pH buffering agents; thus the suspension consisting of these ingredients.

In some embodiments, the sum of constituents of the aqueous suspension (e.g., at least one oxidizing agent; a total amount of less than 0.2 wt.-% of abrasive particles based on a total weight of the aqueous suspension, wherein the abrasive particles have a Mohs hardness of less than 6; and aluminum nitrate) makes up at least 90 wt.-%, at least 95 wt.-%, or at least 98 wt.-% of all ingredients of the suspension of the present disclosure excluding water, the pH adjusting agents and pH buffering agents. In some embodiments, the only ingredients of the suspension of the present disclosure are the at least one oxidizing agent; a total amount of less than 0.2 wt.-% of abrasive particles based on a total weight of the aqueous suspension, wherein the abrasive particles have a Mohs hardness of less than 6, and aluminum nitrate, water, and the pH adjusting agents and pH buffering agents; thus the suspension consisting of these ingredients.

In some embodiments, the aqueous suspension can include (e.g., comprise, consist essentially of, or consist of) 2.0 to 6.0 wt.-% of the one or more metal salts of permanganic acid, 0.05 to 5.0 wt.-% of the zirconia nanoparticles, 0.05 to 5.0 wt.-% of the alumina nanoparticles, and 0.1 to 3.0 wt.-% the one or more salts of nitric acid, water and an inorganic acid to adjust the pH value, the weight percentages being based on the total weight of the aqueous suspension.

In some embodiments, the aqueous suspension can include (e.g., comprise, consist essentially of, or consist of) 2.6 to 5.5 wt.-% of the one or more metal salts of permanganic acid, 0.1 to 2.0 wt.-% of the zirconia nanoparticles, 0.1 to 2.0 wt.-% of the alumina nanoparticles, and 0.2 to 2.0 wt.-% the one or more salts of nitric acid, water and an inorganic acid to adjust the pH value, the weight percentages being based on the total weight of the aqueous suspension.

In some embodiments, the aqueous suspension according to the present disclosure can include (e.g., comprise, consist essentially of, or consist of) of 3.0 to 5.0 wt.-% of the one or more metal salts of permanganic acid, 0.15 to 1.0 wt.-%, of the zirconia nanoparticles, 0.15 to 1.0 wt.-% of the alumina nanoparticles, and 0.5 to 1.5 wt.-% of the one or more salts of nitric acid, the weight percentages being based on the total weight of the aqueous suspension.

In some embodiments, the aqueous suspension according to the present disclosure can include (e.g., comprise, consist essentially of, or consist of) 4.0 to 5.0 wt.-% of the one or more metal salts of permanganic acid, 0.15 to 0.5 wt.-%, of the zirconia nanoparticles, 0.15 to 0.5 wt.-% of the alumina nanoparticles, and 0.5 to 1.0 wt.-% of the one or more salts of nitric acid, the weight percentages being based on the total weight of the aqueous suspension.

In some embodiments, the one or more metal salts of permanganic acid is, e.g., potassium permanganate and/or the inorganic acid to adjust the pH value is nitric acid.

Furthermore, in some embodiments, the pH value of the suspension ranges from 3.0 to 4.0 such as 3.2 to 3.8.

In some embodiments, the aqueous suspension of the present disclosure, comprises, consists essentially of, or consists of: one or more metal salts of permanganic acid in an amount in a range of from 7.5 to 30 wt.-%, from 10 to 25 wt.-%, from 12 to 22 wt.-% such as from 13 to 20 wt.-%; one or more kinds of zirconia nanoparticles in an amount in a range of from 0.05 to 5.0 wt.-%, from 0.10 to 2.0 wt.-%, from 0.15 to 1.0 wt.-% such as from 0.15 to 0.5 wt.-%; one or more kinds of alumina nanoparticles in an amount in a range of from 0.05 to 5.0 wt.-%, from 0.10 to 2.0 wt.-%, from 0.15 to 1.0 wt.-% such as from 0.15 to 0.5 wt.-%; one or more kinds of calcined alumina particles in an amount in a range of from 0.1 to 5.0 wt.-%, from 0.1 to 2.0 wt.-%, such as from 0.1 to 1.0 wt.-%; one or more metal salts of chloric acid in an amount in a range of from 0.1 to 2.0 wt.-%, from 0.1 to 1.0 wt.-%, from 0.2 to 1.0 wt.-%, such as from 0.2 to 0.5 wt.-%; one or more metal salts of perchloric acid in an amount in a range of from 0.1 to 2.0 wt.-%, from 0.1 to 1.0 wt.-%, from 0.2 to 1.0 wt.-%, such as from 0.2 to 0.5 wt.-%; in each case based on the total weight of the aqueous suspension, water, and optionally an inorganic acid such as nitric acid to adjust the pH value to a range of from 3.0 to 5.5, from 3.5 to 5.0, or from 4.0 to 5.0.

In some embodiments, the aqueous suspension can include (e.g., comprise, consist essentially of, or consist of) 1 to 8 wt.-% of at least one oxidizing agent, 0.001 to 0.18 wt.-% of alumina particles, 0.05 to 3 wt.-% of aluminum nitrate, water and optionally an inorganic acid to adjust the pH value, the weight percentages being based on the total weight of the aqueous suspension and the particles (e.g., all particles) being present in the suspension having a Mohs hardness of less than 6.

In some embodiments, the aqueous suspension can include (e.g., comprise, consist essentially of, or consist of) 2 to 6 wt.-% of at least one oxidizing agent, 0.01 to 0.15 wt.-% of alumina particles, and 0.1 to 2 wt.-% of aluminum nitrate, water and optionally an inorganic acid to adjust the pH value, the weight percentages being based on the total weight of the aqueous suspension and the particles (e.g., all particles) being present in the suspension having a Mohs hardness of less than 6.

In some embodiments, the aqueous suspension can include (e.g., comprise, consist essentially of, or consist of) 3 to 5.5 wt.-% of at least one oxidizing agent, 0.08 to 0.12 wt.-% of the alumina particles, and 0.2 to 1.5 wt.-% of aluminum nitrate, the weight percentages being based on the total weight of the aqueous suspension and the particles (e.g., all particles) being present in the suspension having a Mohs hardness of less than 6.

In some embodiments, the aqueous suspension can include (e.g., comprise, consist essentially of, or consist of) 4 to 5 wt.-% of at least one oxidizing agent, 0.1 wt.-% of alumina particles, and 0.3 to 1.0 wt.-% of aluminum nitrate, the weight percentages being based on the total weight of the aqueous suspension and the particles (e.g., all particles) being present in the suspension having a Mohs hardness of less than 6.

In some embodiments, the at least one oxidizing agent is a metal salt of permanganic acid, e.g., potassium permanganate, and/or the inorganic acid to adjust the pH value is nitric acid and/or the aluminum particles can have a Z-average particle size of 75 to 150 nm and/or the alumina particles are γ-AlOOH particles and/or the Mohs hardness of the particles (e.g., all particles) present in the suspension is 3 to 4.

Furthermore, in some embodiments, the pH value of the suspension is in the range from 3 to 4 such as 3.4 to 4.

In some embodiments, exemplary embodiments of the aqueous suspensions of the present disclosure show an excellent pH stability during their shelf life, i.e., the pH drift is less than 0.1 over a period of at least 12 months, as well as high material removal rates despite the low amounts of abrasive particles and excellent surface roughness of the polished substrate. Moreover, the low amount of abrasive particles can be stably suspended in the aqueous carrier without the use of surfactants or dispersing agents, thus avoiding negative influence of such surfactants or dispersing agents on the polishing process. In case of settling, the abrasive particles can be readily resuspended by shaking or stirring the suspension prior to use, thus preventing, reducing, or restricting clogging issues in circulation lines and ensuring a homogenous suspension and material removal rates during polishing.

In some embodiments, the pot life for the aqueous suspension is more than seven days, more than ten days, more than twelve days, or more than fourteen days.

The aqueous suspension of the present disclosure can be a chemical mechanical polishing suspension. In some embodiments, the aqueous suspensions of the present disclosure can be a chemical mechanical polishing suspension adapted for a batch-type and/or single-type chemical mechanical polishing process. Surprisingly, the suspensions of the present disclosure result in high material removal rates and excellent surface roughness of the polished substrate in batch-type as well as single-type CMP processes despite the different process conditions used in these processes.

Suitable substrates to be polished include a ceramic material, a metal, a metal alloy or diamond. In some embodiments, the substrate can be a group III-V compound, for example, gallium nitride, aluminum nitride, indium nitride, indium aluminum nitride, thallium nitride, gallium arsenide, indium gallium arsenide, gallium phosphide, indium antimonide, indium arsenide, boron arsenide or aluminum arsenide. In some embodiments, the substrate can be a group IV-IV compound, for example silicon germanium, silicon tin, diamond, graphene, germanium tin or silicon carbide. In some embodiments, the aqueous suspensions of the present disclosure are adapted for chemical mechanical polishing of a substrate including at least one layer of silicon carbide. The silicon carbide can be single crystal or polycrystalline. In some embodiments, the substrate includes at least one layer of single crystal silicon carbide, such as a single crystal 4H silicon carbide (i.e., 4H—SiC).

In some embodiments, the aqueous suspensions of the present disclosure can be adapted for polishing a substrate, e.g., silicon carbide, with a material removal rate of at least 1.5 μm/hr, at least 2 μm/hr, 2.5 to 12 μm/hr, or 2.5 to 9 μm/hr. Generally, higher material removal rates are achieved in single-wafer CMP processes as compared to batch-type CMP processes, because of the fluctuating polishing conditions occurring in batch-type CMP process which have been mentioned earlier. The material removal rate can be determined by the change in mass of the substrate before and after polishing using the following equation:

$$M R R = \frac{Δ m}{{ρ}_{substrate} π {r}^{2} t}$$

wherein
Δm is the change in mass of the substrate before and after polishing,
ρ_{substrate} is the density of the substrate,
r is the radius of the substrate,
t is the polishing time.

The change in mass of the substrate before and after is divided by the time spent polishing to calculate the material removal rate. The mass of the substrates can be measured using a benchtop scale.

In some embodiments, the surface roughness after polishing the substrate, such as the silicon carbide substrate, with the aqueous suspensions of the present disclosure is less than 0.6 nm, e.g., <0.3 nm. Roughness can be calculated as RMS roughness by AFM metrology (5×5 scan, 1 Hz scan rate). This level of roughness is considered generally desirable and acceptable for downstream substrate processing involving surface epitaxy, e.g., chemical vapor deposition (CVD). Without wishing to be bound to this theory, it is believed that the low surface roughness achieved with the aqueous suspensions of the present disclosure is due to the use of the aluminum nitrate, which results in the formation of a network embedding the abrasive particles. The embedding results in the formation of a “soft” layer on the particle surface, which prevents, reduces, or restricts damage of the surface of the substrate during polishing without negatively influencing the high material removal rates.

The suspensions according to the present disclosure can be supplied as a one-component system including water, at least one oxidizing agent, less than 0.2 wt.-%, based on the total weight of the suspension, of abrasive particles, aluminum nitrate, and optionally the other afore-mentioned ingredients. Such one-component system is a ready-to-use suspension. In some embodiments, the suspensions of the present disclosure are provided in the form of one-component systems, since the suspensions as such are highly storage stable, i.e., they show no pH drift and settling of the abrasive particles, and can readily be used without further mixing and/or dilution steps. Preparation of such one-component systems can be performed as described in relation to the present disclosure for preparing aqueous suspensions.

Alternatively, some of the components, such as the at least one oxidizing agent, can be supplied in a first container, either in dry form, or as aqueous solution, and the remaining components, such as the abrasive particles and aluminum nitrate, can be supplied in a second container or multiple other containers. Other two-container, or three or more container combinations of the components of the suspension according to the present disclosure are within the knowledge of one of ordinary skill in the art. Solid components, such as the abrasive particles, can be placed in one or more containers either in dry form or as a colloidal solution. Moreover, it might be suitable for the components in the first, second, or other containers to have different pH values, or alternatively to have substantially similar, or even equal, pH values. The components of the suspension according to the present disclosure can be partially or entirely supplied separately from each other and can be combined, e.g., by the end-user, shortly before use (e.g., 1 week or less prior to use, 1 day or less prior to use, 1 hour or less prior to use, 10 minutes or less prior to use, or 1 minute or less prior to use).

The suspension according to the present disclosure can also be provided as a concentrate which can be diluted with an appropriate amount of water prior to use. In such an embodiment, the suspension concentrate can include water, at least one oxidizing agent, abrasive particles, aluminum nitrate and optionally other components as discussed in the present disclosure in amounts such that, upon dilution of the concentrate with an appropriate amount of water, each component will be present in the desired suspension in an amount within the appropriate range, e.g., as recited herein, for each component. For example, each component can be present in the concentrate in an amount that is about 1.5 times, e.g., about 2 or more times, greater than the concentration recited above for each component in the aqueous suspension. Upon dilution of the concentrate with an appropriate amount of water, each component will be present in the resulting aqueous suspension in an amount within the ranges set forth above for each component. Furthermore, as will be understood by those of ordinary skill in the art, the concentrate can contain an appropriate fraction of the water present in the final suspension to ensure that the other components of the suspension are at least partially or fully dissolved or suspended in the concentrate. The concentrate can be prepared as described herein in relation to the present disclosure for preparing aqueous suspensions by using higher amounts of each component.

However, the aqueous suspensions of the present disclosure are already highly storage stable at typical storage conditions because the use of aluminum nitrate prevents, reduces, or restricts a pH drift upon storage and thus prevents, reduces, or restricts formation of undesired reaction products, such as manganese dioxide, which result in reduced material removal rates and increased surface roughness. Even if, after several weeks or month of storage, a slight settlement of solid particles might occur, such sediment is readily re-dispersible by agitation such as stirring and/or shaking. Thus, in some embodiments, the aqueous suspensions of the present disclosure are supplied as one-component system described previously.

It may be beneficial to reduce the pH of the aqueous suspensions with nitric acid to 2 to 2.5 (determined at 23° C.) shortly before their use to increase the oxidizing power of the at least one oxidizing agent to ensure a high material removal rate during polishing.

In some embodiments, the suspensions of the present disclosure can be supplied as a one-package system including water, one or more salts of permanganic acid, alumina nanoparticles, zirconia nanoparticles, and one or more salts of nitric acid, and optionally the other afore-mentioned ingredients. Such one-pack system is a ready-to-use suspension. In some embodiments, the suspensions of the present disclosure can be in the form of one-pack systems, since the compositions as such are storage stable and can readily be used without further mixing and/or dilution steps. As such, in some embodiments, it might be suitable to first dissolve the one or more salts of permanganic acid and to supplement the solution with the other ingredients to obtain the one-pack system.

In some embodiments, alternatively or additionally, some of the components, such as one or more salts of permanganic acid, can be supplied in a first container, either in dry form, or in water, and the remaining components, such as the alumina nanoparticles, zirconia nanoparticles, and one or more salts of nitric acid, can be supplied in a second container or multiple other containers. Other two-container, or three or more container combinations of the components of the suspension are part of the present disclosure. Solid components, such as the alumina nanoparticles, zirconia nanoparticles, can be placed in one or more containers either in dry form or as a colloidal solution. Moreover, it might be suitable for the components in the first, second, or other containers to have different pH values, or alternatively to have substantially similar, or even equal, pH values. The components of the suspension can be partially or entirely supplied separately from each other and can be combined, e.g., by the end-user, shortly before use (e.g., 1 week or less prior to use, 1 day or less prior to use, 1 hour or less prior to use, 10 minutes or less prior to use, or 1 minute or less prior to use).

However, the ready-to-use suspensions of the present disclosure are already highly storage stable at typical storage conditions. Even if, after several weeks or month of storage, a slight settlement of solid particles might occur, such sediment is readily re-dispersible by agitation such as stirring and/or shaking. Thus, there is no need for the customer to mix the components only just before use.

In some embodiments, the suspension of the present disclosure can also be provided as a concentrate, which is intended to be diluted with an appropriate amount of water prior to use. The suspension concentrate can include water and optionally other components in amounts such that, upon dilution of the concentrate with an appropriate amount of water, each component will be present in the desired suspension in an amount within the appropriate range recited above for each component. For example, each component can be present in the concentrate in an amount that is about 1.5 times, e.g., about 2 or more times greater than the concentration recited above for each component in the polishing composition So that, when the concentrate is diluted with an appropriate volume of water, each component will be present in the final suspension in an amount within the ranges set forth above for each component. Furthermore, as will be understood by those of ordinary skill in the art, the concentrate can contain an appropriate fraction of the water present in the final suspension in order to ensure that the other components of the suspension are at least partially or fully dissolved or suspended in the concentrate.

In some embodiments, a method for preparing an aqueous suspension, includes (i) adding aluminum nitrate to the aqueous suspension; and (ii) adding an aqueous solution of one or more metal salts of permanganic acid to the aqueous suspension, wherein the aqueous suspension comprises alumina nanoparticles and zirconia particles in water. In some embodiments, prior to the adding the aluminum nitrate, the method includes filtering the aqueous suspension. In some embodiments, prior to the adding the aqueous solution, the method includes filtering the aqueous solution of one or more metal salts of permanganic acid. In some embodiments, the aqueous suspension is absent MnO₂. In some embodiments, the aqueous suspension has a pH value in a range from 2 to 5 at 23° C. In some embodiments, the step (i) of adding aluminum nitrate and the step (ii) of adding an aqueous solution are sequentially carried out. The method steps of the present disclosure can be rearranged, and the order of the steps changed. For example, the first step may be step (ii) and the aqueous solution may be added to the aqueous suspension first. This is not exhaustive list of the method step order. The steps can be rearranged in any order.

In some embodiments, a method for preparing an aqueous suspension, includes (i) adding aluminum nitrate to the aqueous suspension; (ii) adding an aqueous solution of one or more metal salts of permanganic acid, one or more metal salts of perchloric acid, and one or more metal salts of chloric acid to the aqueous suspension; and (iii) adding one or more kinds of calcined alumina particles to the aqueous suspension, wherein the aqueous suspension comprises alumina nanoparticles and zirconia particles. In some embodiments, prior to the adding the aluminum nitrate, the method includes filtering the aqueous suspension. In some embodiments, prior to the adding the aqueous solution, the method includes filtering the aqueous solution. In some embodiments, the aqueous suspension is absent MnO₂. In some embodiments, the aqueous suspension has a pH value in a range from 2 to 5 at 23° C. In some embodiments, the step (i) of adding aluminum nitrate, the step (ii) of adding an aqueous solution, and the step (iii) of adding one or more kinds of calcined alumina particles are sequentially carried out. The method steps of the present disclosure can be rearranged, and the order of the steps changed. For example, the first step may be step (ii), where the aqueous solution may be added to the aqueous suspension first, followed by step (iii) and then step (i). In some examples, step (iii) may be first followed by step (ii) and then step (i). This is not exhaustive list of the method step order. The steps can be rearranged in any order (e.g., step (iii), step (i) and then step (ii)).

In some embodiments, the present disclosure includes a method for preparing an aqueous suspension, including (i) adding aluminum nitrate to the aqueous suspension; and (ii) adding an aqueous solution of at least one oxidizing agent to the aqueous suspension obtained. In some embodiments, the aqueous suspension includes abrasive particles. In some embodiments, the abrasive particles have a Mohs hardness of less than 6. In some embodiments, the aqueous suspension contains less than 0.2 wt.-% of the abrasive particles based on a total weight of the aqueous suspension. In some embodiments, prior to the adding the aluminum nitrate, the method includes filtering the aqueous suspension. In some embodiments, prior to the adding the aqueous solution, the method includes filtering the aqueous solution. In some embodiments, the aqueous suspension is absent MnO₂. In some embodiments, the aqueous suspension has a pH value in a range from 2 to 5 at 23° C. In some embodiments, the step (i) of adding aluminum nitrate and the step (ii) of adding an aqueous solution are sequentially carried out. The method steps of the present disclosure can be rearranged, and the order of the steps changed. For example, the first step may be step (ii), where the aqueous solution may be added to the aqueous suspension first, followed by step (i). This is not exhaustive list of the method step order. The steps can be rearranged in any order.

A further object of the present disclosure is a method for preparing an aqueous suspension (AS) having a pH value at 23° C. of 2 to 5, including:
(A) providing an aqueous suspension of abrasive particles (ASP), wherein all abrasive particles present in the aqueous suspension (ASP) have a Mohs hardness of less than 6,
(B) adding aluminum nitrate to the aqueous suspension (ASP) provided in step (A),
(C) adding an aqueous solution of at least one oxidizing agent to the aqueous suspension obtained after step (B), and
(D) optionally adjusting the pH of the aqueous suspension (AS) resulting after step (C) with at least one pH adjusting agent

In some embodiments, the aqueous suspension (AS) resulting from the present disclosure contains less than 0.2 wt.-%, based on the total weight of the aqueous suspension, of abrasive particles. Thus, the amount of abrasive particles present in the aqueous suspension provided in step (A) is selected such that the aqueous suspension resulting from the method of the present disclosure contains less than 0.2 wt.-% of abrasive particles. This may be achieved by considering the amount of water being present in the aqueous oxidizer solution used in step (C) or by diluting the aqueous suspension resulting from step (C) or (D) with water as described herein.

Step (A):

In step (A) of the present disclosure, an aqueous suspension of abrasive particles is provided. This may include preparing an aqueous suspension by mixing a dry powder of abrasive particles with a suitable amount of water, diluting a commercially available aqueous suspension of abrasive particles with a suitable amount of water or using a commercially available suspension of abrasive particles. The suspension may be filtered prior to step (B) to avoid the presence of larger agglomerates, because these agglomerates can result in scratching of the substrate during polishing, thus increasing the surface roughness and therefore decreasing the quality of the polished product. In some embodiments, step (A) includes providing an aqueous suspension of colloidal alumina nanoparticles (i.e., alumina particles having a Z-average particle size of 1 to 1000 nm) by mixing dry alumina powder with water and filtering the resulting suspension. Suitable abrasive particles which can be used in step (A) of the method of the present disclosure includes the abrasive particles described herein in relation to the aqueous suspensions of the present disclosure.

The aqueous suspension provided in step (A) may include the abrasive particles in a total amount of 0.1 to 3 wt.-%, e.g., 0.2 to 1 wt.-%, based in each case on the total amount of the aqueous suspension provided in step (A).

Step (B):

In step (B) of the present disclosure, aluminum nitrate is added to the aqueous suspension of abrasive particles provided in step (A). Addition of aluminum nitrate results in an increase in viscosity of the aqueous suspension provided in step (A), which indicates the formation of a network structure embedding the abrasive particles.

The amount of aluminum nitrate added in step (B) can be 0.5 to 5 wt.-%, e.g., 1 to 3 wt.-%, based in each case on the total amount of the aqueous suspensions (ASP). These amounts ensure that a sufficient amount of network structure is formed such that the abrasive particles are fully covered with a soft layer and are stably suspended in the aqueous carrier. Moreover, these amounts ensure that a pH drift of the aqueous suspensions prepared by the method of the present disclosure upon storage and therefore the formation of undesired reaction products, such as manganese dioxide, is prevented, reduced, or restricted because the reaction products reduce the material removal rate and increase the surface roughness.

Step (C):

In step (C) of the method of the present disclosure, an aqueous solution of at least one oxidizing agent is added to the mixture obtained after step (B). This solution can be prepared by adding a suitable amount of oxidizing agent(s), e.g., water-soluble oxidizing agent(s), to a suitable amount of water or by diluting a concentrated aqueous solution of oxidizing agent(s) with water to obtain the desired concentration of the oxidizing agent(s) in the aqueous solution. In some embodiments, the obtained aqueous solution of the oxidizing agent may be filtered prior to adding the aqueous solution to the mixture obtained in step (B) to avoid the presence of undissolved oxidizing agent particles, because these particles can result in scratching of the substrate during polishing, thus increasing the surface roughness and therefore decreasing the quality of the polished product. Suitable oxidizing agents have been described previously in relation to the aqueous suspensions of the present disclosure. In some embodiments, an aqueous solution of potassium permanganate is used in step (C).

The aqueous solution added in step (C) may include the at least one oxidizing agent in a total amount of 1 to 10 wt.-%, e.g., 3 to 6 wt.-%, based in each case on the total amount of the aqueous solution added in step (C).

Optional Step (D):

In optional step (D), the pH of the aqueous suspension resulting from step (C) is adjusted with at least one pH adjusting agent. In some embodiments, the use of appropriate amounts of aluminum nitrate already provides aqueous suspensions after step (C) which have the desired pH, optional step (D) use is not required and not used.

Further Step (E):

The method of the present disclosure may include at least one further step (E). In a first alternative of this step, the aqueous suspension obtained after step (C) is diluted with water prior to performing step (D). In a second alternative of this step, the aqueous suspension obtained after step (D) is diluted with water. In some embodiments, the further step (E) may be beneficial to ensure that the total amount of abrasive particles in the aqueous suspension produced with the method of the present disclosure is less than 0.2 wt.-%, based on the total weight of the produced aqueous suspension.

What has been said about the aqueous suspensions of the present disclosure, in particular about the components of the aqueous suspensions applies mutatis mutandis with respect to further embodiments of the method for preparing an aqueous suspension.

The suspension of the present disclosure is useful as a polishing composition, suitable for polishing of silicon carbide surfaces, e.g., in a chemical mechanical planarization method.

In some embodiments, the method of the present disclosure includes storing an aqueous suspension (e.g., the aqueous suspension of the present disclosure), having a pH ranging from 3 to 5; reducing the pH of the aqueous suspension to range from 2 to 2.5; and using the aqueous suspension having the pH ranging from 2 to 2.5 within fourteen days. In some embodiments, storing the aqueous suspension includes storing the aqueous suspension for at least 1 year.

In some embodiments, reducing the pH of the initial aqueous suspension includes adding an acid. The acid can include nitric acid. In some embodiments, reducing the pH of the initial aqueous suspension to the range of 2 to 2.5 includes reducing the pH of the initial aqueous suspension to 2.3. In some embodiments, using the reduced aqueous suspension includes using the reduced aqueous suspension in a single-type chemical mechanical planarization method and/or a batch-type chemical mechanical planarization method.

The present disclosure further provides a method of chemically-mechanically planarizing a substrate (i.e., a CMP method), which includes contacting a substrate, e.g., a silicon carbide surface such a silicon carbide wafer surface with an aqueous suspension according to the present disclosure; moving the aqueous suspension by means of a polishing pad relative to the substrate; and abrading at least a portion of the substrate to polish and/or planarize the substrate. In some embodiments, during the abrading, the substrate does not exceed a temperature of 60° C., 59° C., 58° C., 57° C., 56° C., 55° C., 54, 53° C., 52° C., 51° C., 50° C., or any intervening number (e.g., 56.3° C.).

The CMP method according to the present disclosure can be used in conjunction with a chemical mechanical polishing (CMP) apparatus/tool/device. Any of the commonly-known CMP apparatuses, which are common to the industry, including those from such vendors as Applied Materials, Revasum, Axus, Lapmaster Wolters, and Ibarra, can be used in the CMP method of the present disclosure.

The apparatus can include a platen, which, when in use, is in motion and has a velocity that results from orbital, linear, or circular motion, a polishing pad in contact with the platen and moving with the platen when in motion, and a carrier that holds the substrate to be polished by contacting and moving relative to the surface of the polishing pad. The polishing of the substrate takes place by the substrate being placed in contact with the polishing pad and the suspension of the present disclosure (which generally is disposed between the substrate and the polishing pad), with the polishing pad moving relative to the substrate, to abrade at least a portion of the substrate to polish and/or planarize the substrate.

In some embodiments, the substrate is a silicon carbide substrate. In some embodiments, the polishing end-point is determined by monitoring the weight of the silicon carbide substrate, which is used to compute the amount of silicon carbide removed from the substrate. Such techniques are well known in the art. For example, the polishing end-point is determined by monitoring the weight of the substrate as described previously in relation to the determination of the material removal rate. Polishing refers to the removal of at least a portion of a surface to polish the surface. Polishing can be performed to provide a surface having reduced surface roughness by removing gouges, crates, pits, and the like, but polishing also can be performed to introduce or restore a surface geometry characterized by an intersection of planar segments. The method of the present disclosure can be used to polish and/or planarize any suitable substrate, e.g., those including at least one layer of silicon carbide.

In some embodiments, before contacting the substrate with the aqueous suspension, the method includes reducing a pH of the aqueous suspension to a range of 2 to 2.5. The reducing step can include adding an acid. The pot life of the aqueous suspension is the useable life of the aqueous suspension after the aqueous suspension is reduced, e.g., to a pH range of 2 to 2.5. The shelf life of the aqueous suspension can be, as described herein, can be greater than one year.

In some embodiments, after storing the aqueous suspension for up to and greater than one year, the aqueous suspension will be reduced (e.g., adding an acid to the aqueous suspension) shortly before use. After the aqueous suspension is reduced, the aqueous suspension will have a working life, after which the aqueous suspension may not be useable for its intended purposes. The working life of the aqueous suspension is referred to as the pot life. In some embodiments, the pot life can be at least five, seven, ten, twelve, or fourteen days. To ensure the aqueous suspension is used during its pot life, in some embodiments, the method of the present disclosure includes contacting the substrate with the reduced aqueous suspension within a set timeframe of the reducing step. For example, the method includes contacting the substrate with the reduced aqueous suspension within five, seven, ten, twelve, or fourteen days of the reducing step. This ensures the reduced aqueous suspension contacts the substrate during its pot life.

The suspension in conjunction with a polishing pad is an integral component of the chemical mechanical planarization method claimed in the present disclosure. In some embodiments, the type and material of polishing pads to be used in the CMP method of the present disclosure is not critical for the present disclosure. Virtually any conventionally used polishing pad for use in a CMP method for planarizing silicon carbide wafers can be used. Suitable polishing pads include, for example, woven and non-woven polishing pads. Moreover, suitable polishing pads can include any suitable polymer of varying density, hardness, thickness, compressibility, ability to rebound upon compression, and compression modulus. Suitable polymers include, for example, polyvinylchloride, polyvinyl fluoride, nylon, fluorocarbon, polycarbonate, polyester, polyacrylate, polyether, polyethylene, polyamide, polyurethane, polystyrene, polypropylene, conformed products thereof, and mixtures thereof. In some embodiments, polyurethane pads can be used. Conventional pads may be made one at a time or as a cake which is subsequently sliced into individual pad substrates. These substrates are then machined to a final thickness and grooves are further machined onto them. Polymer or polymer/fiber circular pads can be 1 mm to 4 mm thick. The polishing pad can have any suitable configuration. For example, the polishing pad can be circular and, when in use, will have a rotational motion about an axis perpendicular to the plane defined by the surface of the pad. The polishing pad can be cylindrical, the surface of which acts as the polishing surface, and, when in use, can have a rotational motion about the central axis of the cylinder. The polishing pad can be in the form of an endless belt, which, when in use, can have a linear motion with respect to the cutting edge being polished. The polishing pad can have any suitable shape and, when in use, have a reciprocating or orbital motion along a plane or a semicircle. Many other variations are readily apparent to the skilled artisan.

The conventional polymer-based CMP polishing pads are typically adhered using a pressure sensitive adhesive to a flat rotating circular table within a CMP machine.

The substrate to be polished using the CMP method of the present disclosure can be any suitable substrate, e.g., those which include at least one layer of silicon carbide. Suitable substrates include, but are not limited to, flat panel displays, integrated circuits, memory or rigid disks, metals, interlayer dielectric (ILD) devices, semiconductors, micro-electro-mechanical systems, ferroelectrics, and magnetic heads. The silicon carbide can comprise, consist essentially of, or consist of any suitable silicon carbide, many of which are known in the art. For example, the substrate can be a silicon carbide substrate. The silicon carbide can be single crystal or polycrystalline. As already explained above, silicon carbide has many different types of crystal structures, each having its own distinct set of electronic properties. Only a small number of these polytypes, however, can be reproduced in a form acceptable for use as semiconductors. Such polytypes can be either cubic (e.g., 3C silicon carbide) or non-cubic (e.g., 4H silicon carbide, 6H silicon carbide). The properties of these polytypes are well known in the art. In some embodiments, the substrate to be used in the CMP method of the present disclosure is 4H silicon carbide (i.e., 4H—SiC).

The effective polishing temperature for polishing the SiC wafers in the CMP method of the present disclosure, i.e., the temperature measured on the polishing pad during polishing, and typically being recorded on an IR thermometer, is several degrees centigrade lower that observed for similar configurations using commercially available slurries.

The lower temperature of the suspensions of the present disclosure and the suspensions prepared according to the method of the present disclosure yields benefits including, in that CMP methods can be run at either a) a lower temperature, thus yielding a gentler process that is less prone to surface defectivity and thus generates higher process yields, or b) higher material removal rates, by increasing the pressures on polishing pads and/or increasing the speed of the CMP to higher levels than allowed for conventional suspensions. Depending on the specific aims to be achieved, e.g., yield versus throughput, these temperature-related benefits are profoundly valuable.

The upper limit of the polishing temperature is however limited by the polishing pad material, which is desired to have little or no degradation during the CMP method. Typically, the polishing temperature does not exceed 60° C.

The flow rate at which the suspension of the present disclosure is dispensed on the CMP apparatus depends on the specific apparatus and pad configuration which are used. However, the suspension of the present disclosure works well at industry standard flow rates.

With the CMP method of the present disclosure using the suspensions of the present disclosure silicon carbide can be removed at material removal rates of about 3 to 15 μm/hour, typically 5 to 12 μm/hour or 6 to 10 μm/hour without damaging the surface and thus providing scratch-free silicon carbide surfaces—that is, surfaces which are measured using a confocal optical microscopy technique with automated scratch detection and characterization metrology, shown to be free of CMP-related scratching which is sometimes present due to other slurries, pads, tools, etc.

In a typical CMP process, the scratch length per wafer might be expected to be <20 mm, but this is highly dependent on the customer's process, tool, pad, wafer quality, etc. However, the suspensions of the present disclosure used in the CMP method of the present disclosure provide a significant improvement regarding the occurrence of scratches and their length, which is typically significantly lower than the above-mentioned value, if scratches occur at all.

The suspensions of the present disclosure provide SiC wafer surfaces having a surface roughness of less than 1 Angstrom. Roughness is calculated as RMS roughness by AFM metrology (5×5 scan, 1 Hz scan rate). This level of roughness is considered generally desirable and acceptable for downstream silicon carbide processing involving surface epitaxy, e.g., chemical vapor deposition (CVD).

Finally, the suspension allows an extraordinarily low CMP polishing temperature. The polishing temperature is routinely lower than the temperature used with prior art slurries. The lower temperature of the suspensions of the present disclosure, gives a huge benefit, in that CMP methods can be run at either a) a lower temperature, thus yielding a gentler process that is less prone to surface defectivity and thus generates higher process yields, or b) higher material removal rates, by increasing the pressures on polishing pads and/or increasing the speed of the CMP to higher levels than allowed for conventional suspensions. Depending on the specific aims to be achieved, e.g., yield versus throughput, these temperature-related benefits are valuable.

What has been said about the aqueous suspensions of the present disclosure, in particular about the components of the aqueous suspensions, and the method to prepare aqueous suspensions applies mutatis mutandis with respect to further embodiments of the method of chemically-mechanically planarizing a substrate.

### EXAMPLES

The following examples further illustrate the present disclosure but, of course, are not to be construed as in any way limiting its scope.

### Example 1 (Comparative)

This example demonstrates the concentration effect of alumina nanoparticles on single crystal SiC polishing temperature and material removal rates. Polishing temperature and removal rates were determined for each aqueous suspension containing 4 wt.-% of KMnO₄ and 0.5 wt.-% of salts of nitric acid at pH 2.3 and the results are shown in Table 1.

TABLE 1

| Alumina | | |
|---|---|---|
| nanoparticle | Polishing | Silicon carbide |
| concentration | Temperature | Removal Rate |
| [wt.-%] | (° C.) | (μ/hr) |
| 0.1% | 46.4 | 5.8 |
| 0.2% | 45.2 | 5.2 |
| 0.5% | 41.4 | 4.5 |
| 1% | 35.5 | 3.1 |
| 5% | 28.7 | 1.2 |

The increase in abrasive concentration shows decrease in temperature and at the same time it also decreases the silicon carbide removal rates.

### Example 2 (Comparative)

This example shows the concentration effect of zirconia nanoparticles on single crystal SiC polishing temperature and material removal rates. Polishing temperature and removal rates were determined for each aqueous suspension containing 4 wt.-% of KMnO₄ and 0.5 wt.-% of salts of nitric acid at pH 2.3 and results are shown in Table 2.

TABLE 2

| Zirconia | | |
|---|---|---|
| nanoparticle | Polishing | Silicon carbide |
| concentration | Temperature | Removal Rate |
| [wt.-%] | (° C.) | (μ/hr) |
| 0.1% | 51.5 | 7 |
| 0.2% | 48.2 | 6.4 |
| 0.5% | 45.8 | 4.8 |
| 1% | 40.3 | 3.5 |
| 5% | 33 | 1.7 |

Temperature and removal rates of zirconia nanoparticles showed a trend similar to alumina nanoparticles. However, presence of zirconia particles enhanced SiC removal rates up to ˜20% compared to similar concentration of alumina nanoparticles.

### Example 3 (Comparative)

This example shows the combination of alumina and zirconia nanoparticles effect on single crystal SiC polishing temperature and material removal rates. Polishing temperature and removal rates were determined for each aqueous suspension containing 4.5 wt.-% of KMnO₄ and 0.75 wt.-% of salts of nitric acid at pH 2.3 each composition and results are shown in Table 3.

TABLE 3

| | Polishing | Silicon carbide |
|---|---|---|
| Nanoparticle | Temperature | Removal Rate |
| Concentration [wt.-%] | (° C.) | (μ/hr) |
| 0.1% alumina + 0.1% zirconia | 49.7 | 9.4 |
| 0.25% alumina + 0.25% zirconia | 46.4 | 10.8 |
| 0.5% alumina + 0.5% zirconia | 44.8 | 8.7 |
| 0.2% alumina + 0.8% zirconia | 45.3 | 10.2 |
| 1% alumina + 1% zirconia | 42.8 | 7.9 |

Synergistic effect of alumina and zirconia nanoparticles showed significant increase in removal rates as high as ˜11 μ/hr. At the same time a considerable decrease in temperature was observed.

Atomic force microscopy (AFM) data of single crystal SiC (Si-face) surface roughness (Rₐ) measurement data using the mixed particles (alumina+zirconia) samples is given in Table 4.

TABLE 4

| Nanoparticle | Surface |
|---|---|
| Concentration | roughness Rₐ |
| [wt.-%] | (nm) |
| 0.1% alumina + 0.1% zirconia | 0.23 |
| 0.25% alumina + 0.25% zirconia | 0.0636 |
| 0.5% alumina + 0.5% zirconia | 0.17 |
| 0.2% alumina + 0.8% zirconia | 0.0842 |
| 1% alumina + 1% zirconia | 0.23 |

Mixed particles produce sub A° surface roughness with quality SiC substrates.

### Example 4 (Example of the Present Disclosure)

This example shows the combination of alumina and zirconia nanoparticles and calcined alumina (these constituents are together referred to in Table 5 as abrasive) and further constituents (chlorates, perchlorates, together referred to in Table 5 as additive) effect on single crystal SiC (Si-face) polishing temperature and material removal rates. Polishing temperature and removal rates were determined for each aqueous suspension containing 15 wt.-% of permanganic acid (KMnO₄, NaMnO₄) and 0.75 wt.-% of salts of nitric acid at pH 2.3, each composition and results are shown in Table 5.

TABLE 5

| | Polishing | Silicon carbide |
|---|---|---|
| Concentration | Temperature | Removal Rate |
| [wt.-%] | (° C.) | (μ/hr) |
| 6% abrasive + 0% Additive | 42.8 | 10.5 |
| (comparative) | | |
| 4% abrasive + 1% Additive | 48.5 | 12.3 |
| 5% abrasive + 0.5% Additive | 47.2 | 13.2 |
| 6% abrasive + 1.5% Additive | 52 | 14 |

Data given in Table 5 clearly shows the importance of balancing chemical activity and mechanical abrasion to achieve high material removal rates along with acceptable process temperature. Zero percent additive with high abrasive concentration (6% abrasive) decreases removal rates with decrease in process temperature. Synergistic effects of abrasive and additive showed significant increase in removal rates as high as 14 μ/hr at acceptable process temperatures.

Atomic force microscopy (AFM) data of single crystal SiC (Si-face) surface roughness (Rₐ) measurements obtained on polished SiC (Si-face) wafers using the above given concentrations (Table 5) are shown in Table 6.

TABLE 6

| | Surface |
|---|---|
| Concentration | roughness Ra |
| [wt.-%] | (nm) |
| 6% abrasive + 0% Additive | 0.1 |
| 4% abrasive + 1% Additive | 0.092 |
| 5% abrasive + 0.5% Additive | 0.0667 |
| 6% abrasive + 1.5% Additive | 0.258 |

It is apparent from the data shown in Table 6 that this slurry provides scratch free sub A° level surface roughness (Rₐ) which enhance SiC wafer throughput. A high concentration of chemically active ions in combination with high concentration of particles yield increase in single crystal SiC (Si-face) material removal rates with acceptable process temperature with an excellent surface finish. Hence, all these performance benefits make these slurries viable for all SiC process applications (i.e., batch process, single wafer process).

The present disclosure will now be explained in greater detail through the use of the following working examples, but the present disclosure is in no way limited to these working examples. Moreover, the terms “parts”, “%” and “ratio” in the examples denote “parts by mass”, “mass %” and “mass ratio” respectively unless otherwise indicated.

1. Methods of Determination:

1.1 Material Removal Rate

The material removal rate (MRR) is by the change in mass of the substrate before and after polishing according to the previously mentioned equation. The change in mass of the substrate before and after is divided by the time spent polishing to calculate the material removal rate. The mass of the substrates is measured using a benchtop scale. The material removal rate is determined for each wafer polished in one batch-polishing process and is averaged over three consecutive batch-polishing processes.

1.2 Surface Roughness

Surface roughness is calculated as RMS roughness by AFM metrology (5×5 scan, 1 Hz scan rate) by measuring the surface roughness of each SiC substrate at three locations. If the surface roughness is repetitive at these three locations, the respective value is given as surface roughness.

1.3 Storage Stability

Storage stability of the prepared suspensions was determined by measuring the pH at 23° C. for a period of 12 month and by visual evaluation of the suspensions at the end of the storage time.

2. Preparation of the Examples of the Present Disclosure and Comparative Aqueous Suspensions

Example aqueous suspensions of the present disclosure and comparative aqueous suspensions were prepared using one of the following methods:

Method A (Example of the Present Disclosure):

Step A1: An aqueous suspension including the alumina particles and aluminum nitrate was prepared by mixing an aqueous slurry of alumina particles (prepared by dispersion alumina particles having a Mohs hardness of 3 to 4 in water and filtering the resulting dispersion) and aluminum nitrate.

Step A2: An aqueous solution of potassium permanganate was prepared by dissolving potassium permanganate in water.

Step A3: The aqueous solution of potassium permanganate prepared in step A2 was added to the aqueous suspension prepared in step A1.

The amounts of alumina particles, aluminum nitrate, potassium permanganate and water used in steps A1 and A2 are chosen such that the amounts given in Table 7 result after the end of step A3.

Comparative Method B (Comparative):

Step B1: An aqueous solution of potassium permanganate was prepared by dissolving potassium permanganate in water.

Step B2: the aqueous slurry of alumina particles and aluminum nitrate are added to the aqueous solution prepared in step B1.

The amounts of alumina particles, aluminum nitrate, potassium permanganate and water used in steps B1 and B2 are chosen such that the amounts given in Table 7 result after the end of step B2.

The final composition of all prepared Examples of the present disclosure and comparative aqueous suspensions is given in Table 7.

TABLE 7
Overview of prepared Examples of the present disclosure and comparative aqueous suspensions (all
amounts are given in wt.-%, based on the total weight of the respective aqueous suspension)

| Compound | S-I1* | S-C1 | S-C2 | S-C3 | S-C4 | S-C5 | S-C6 | S-C7 | S-C8 | S-C9 |
|---|---|---|---|---|---|---|---|---|---|---|
| Potassium | 4.0 | 4.0 | 4.0 | 4.0 | 4.0 | 4.0 | 4.0 | 4.0 | 4.0 | 4.0 |
| permanganate | | | | | | | | | | |
| Aluminum | 0.50 | 0.50 | 0.50 | 0.5 | 0.5 | 0.50 | — | — | — | — |
| nitrate | | | | | | | | | | |
| Ferric | — | — | — | — | — | — | 0.5 | — | — | — |
| nitrate | | | | | | | | | | |
| Cerium | — | — | — | — | — | — | — | 0.5 | — | — |
| nitrate | | | | | | | | | | |
| Cerium | — | — | — | — | — | — | — | — | 0.5 | — |
| ammonium | | | | | | | | | | |
| nitrate | | | | | | | | | | |
| Manganese | — | — | — | — | — | — | — | — | — | 0.5 |
| nitrate | | | | | | | | | | |
| alumina | 0.10 | 0.20 | 0.50 | 1.0 | 5.0 | 0.10 | 0.10 | 0.10 | 0.10 | 0.10 |
| particles ¹ | | | | | | | | | | |
| Distilled | 95.4 | 95.3 | 95.0 | 94.5 | 90.5 | 95.4 | 95.4 | 95.4 | 95.4 | 95.4 |
| water | | | | | | | | | | |
| pH (23° C.) | 3.6-3.8 | 3.6-3.8 | 3.8-4.0 | 3.9-4.1 | 4.4-4.8 | 3.6-3.8 | 3.8-4.0 | 3.8-4.0 | 4.0-4.2 | 3-3.2 |
| Preparation | MA² | MA² | MA² | MA² | MA² | MB³ | MA² | MA² | MA² | MA² |
| method | | | | | | | | | | |

* Example of the present disclosure
¹ boehmite particles with a Z-average particle size of 100 nm (supplied by Sasol Performance Chemicals)
² MA is an abbreviation for Method A
³ MB is an abbreviation for Method B

3. CMP Process

The polishing properties of the inventive aqueous suspension S-I1 and the comparative aqueous suspensions S-C1 to S-C9 were each tested and compared by polishing 16 silicon carbide substrates in a batch-type CMP process using a batch-type CMP tool and in a single-type CMP process using a commercially available single-type CMP tool. The silicon carbide substrates were each a 4H-type round wafer with a diameter of 150 nm. Prior to polishing, the pH of each composition was reduced to 2.1 with nitric acid.

4. Results

4.1 Storage Stability

The storage stability was determined as described in the Storage stability section above (Section 1.3) and the obtained results are listed in Table 8.

TABLE 8
Results of storage stability tests

| | Initial | pH after 12 | |
|---|---|---|---|
| Slurry | pH @23° C. | month @23° C. | Visual observation |
| S-I1* | 3.6-3.8 | 3.6-3.8 | Bright purple color after |
| | | | preparation, no color change |
| | | | and settling upon storage |
| | | | for 12 month |
| S-C1 | 3.6-3.8 | 3.6-3.8 | Bright purple color after |
| | | | preparation, no color change |
| | | | and settling upon storage |
| | | | for 12 month |
| S-C2 | 3.8-4.0 | 3.8-4.0 | Bright purple color after |
| | | | preparation, no color change |
| | | | and settling upon storage |
| | | | for 12 month |
| S-C3 | 3.9-4.1 | 3.9-4.1 | Bright purple color after |
| | | | preparation, no color change |
| | | | and settling upon storage |
| | | | for 12 month |
| S-C4 | 4.4-4.8 | n.d. ¹⁾ | Bright purple color after |
| | | | preparation, settling |
| | | | upon storage, not stable |
| S-C5 | 3.6-3.8 | n.d. ¹⁾ | Bright purple color after |
| | | | preparation, no color change |
| | | | but settling after storage, |
| | | | not stable |
| S-C6 | 3.8-4.0 | n.d. ¹⁾ | Bright purple color after |
| | | | preparation, color change |
| | | | to dark brown upon storage |
| S-C7 | 3.8-4.0 | n.d. ¹⁾ | Bright purple color after |
| | | | preparation, color change |
| | | | to dark brown upon storage |
| S-C8 | 4.0-4.2 | n.d. ¹⁾ | Bright purple color after |
| | | | preparation, color change |
| | | | to dark brown and settling |
| | | | upon storage for 2-3 days |
| S-C9 | 3.4-3.6 | n.d. ¹⁾ | Bright purple color after |
| | | | preparation, color change |
| | | | to dark brown upon storage |
| | | | for 1 week |

*Example of the present disclosure
¹⁾ not determined

The results shown in Table 8 demonstrate that aqueous suspensions which are prepared according to the method of the present disclosure and which include aluminum nitrate and less than 5 wt.-% of alumina particles (S-I1, S-C1 to S-C3) do not show a pH drift as well as a color change upon storage of 12 month, thus allowing to obtain a constant polishing quality irrespective of the storage time. In contrast, aqueous suspension S-C4 being prepared according to the method of the present disclosure and including aluminum nitrate and 5 wt.-% alumina particles settles upon storage and is therefore not storage stable. Aqueous suspension S-C5, which contains the same amounts of aluminum nitrate, alumina particles and potassium permanganate than the aqueous suspension S-I1 of the present disclosure, but was not prepared according to the method of the present disclosure is also not stable upon storage. Upon storing of aqueous suspensions S-C6 to S-C9 containing other nitrates than aluminum nitrate, undesirable manganese dioxide is formed due to a pH drift to higher pH values. The presence of manganese dioxide, however, results in increased surface roughness and reduced material removal rates of the stored suspensions (see Tables 9 and 11 below) and is thus not desired.

4.2 Silicon Carbide Removal Rate

The silicon carbide removal rate was determined as described in Section 1.1 above and the obtained results are listed in Tables 9 and 10.

TABLE 9
Results for silicon carbide removal rates for aqueous suspensions
S-I1 and S-C1 to S-C9 in a batch-type CMP process.

| | Amount | | |
|---|---|---|---|
| | alumina | | Silicon carbide |
| | particles | | removal rate |
| Slurry | [wt.-%] | Nitrate | [μm/hr] |
| S-I1* | 0.1 | Aluminum nitrate | 3 |
| S-C1 | 0.2 | Aluminum nitrate | 3.8 |
| S-C2 | 0.5 | Aluminum nitrate | 4.2 |
| S-C3 | 1.0 | Aluminum nitrate | 4.8 |
| S-C4 | 5.0 | Aluminum nitrate | n.d. ¹⁾ |
| S-C5 | 0.1 | Aluminum nitrate | 2.5 |
| S-C6 | 0.1 | Ferric nitrate | 2.8 |
| S-C7 | 0.1 | Cerium nitrate | 2.1 |
| S-C8 | 0.1 | Cerium ammonium | n.d ¹⁾ |
| | | nitrate | |
| S-C9 | 0.1 | Manganese nitrate | n.d ¹⁾ |

*Example of the present disclosure
¹⁾ not determinable due to instability of aqueous suspensions S-C4, S-C8 and S-C9

TABLE 10
Results for silicon carbide removal rate for inventive
aqueous slurry S-I1 used in a single-type CMP
process using different down pressures

| | Silicon carbide |
|---|---|
| Down pressure (PV) | removal rate |
| [psi*in/sec] | [μm/hr] |
| 972 | 8 |
| 675 | 4.9 |
| 405 | 2.6 |

Batch-Type CMP Process:

Comparative aqueous slurry S-C5 containing 0.1 wt.-% alumina particles and aluminum nitrate but not having been prepared according to the present disclosure process results in a lower material removal rate in batch-type CMP processes than inventive aqueous slurry S-I1 having an identical composition but being prepared according to the present disclosure process. Moreover, comparative aqueous suspensions S-C6 and S-C7 containing ferric nitrate or cerium nitrate result in lower material removal rates than the present disclosure aqueous slurry S-I1 containing aluminum nitrate. A material removal rate for comparative aqueous suspensions S-C5, S-C8 and S-C9 could not be determined due to their low stability after preparation (see Table 8 above). Comparative aqueous suspensions S-C1 to S-C3 containing a higher amount of alumina particles than inventive aqueous suspension S-I1 result in higher material removal rates. However, the increase in the material removal rate is associated with an undesirable significant increase in surface roughness of the polished product (see Table 11 below). In conclusion, only the present disclosure aqueous suspension S-I1 shows a good balance between material removal rate and surface roughness while higher amounts of alumina particles result in unacceptable surface roughness and the use of other nitrates results in reduced material removal rates as well as an unacceptable surface roughness.

Single-Type CMP Process:

The present disclosure aqueous suspension S-I1 allows to achieve high material removal rates as well as an excellent surface roughness (see Table 12 below) even at high down pressures and thus results in an efficient and fast polishing process providing a high yield (i.e. substrates having a high surface quality).

4.3 Surface Roughness

The surface roughness was determined as described in Section 1.2 above and the obtained results are listed in Tables 11 and 12.

TABLE 11
Results for surface roughness measurements of
SiC-wafers polished in a batch-type CMP process

| | Amount alumina | | Surface | |
|---|---|---|---|---|
| | particles | | roughness Rₐ | |
| Slurry | [wt.-%] | Nitrate | [nm] | |
| S-I1* | 0.1 | Aluminum nitrate | ≤0.3 | nm |
| S-C1 | 0.2 | Aluminum nitrate | ≤0.6 | nm |
| S-C2 | 0.5 | Aluminum nitrate | ≤2 | nm |
| S-C3 | 1.0 | Aluminum nitrate | ≤8 | nm |

| | | | |
|---|---|---|---|
| S-C4 | 5.0 | Aluminum nitrate | n.d. ¹⁾ |
| S-C5 | 0.1 | Aluminum nitrate | Not determined |
| S-C6 | 0.1 | Ferric nitrate | High Scratching |
| S-C7 | 0.1 | Cerium nitrate | High Scratching |
| S-C8 | 0.1 | Cerium ammonium | n.d. ¹⁾ |
| | | nitrate | |
| S-C9 | 0.1 | Manganese nitrate | n.d. ¹⁾ |

*Example of the present disclosure
¹⁾ not determinable due to instability of aqueous suspensions S-C4, S-C8 and S-C9

TABLE 12
Results for surface roughness measurements of
SiC-wafers polished using inventive aqueous
slurry S-Il used in a single-type CMP process

| | Surface |
|---|---|
| Down pressure (PV) | roughness Rₐ |
| [psi*in/sec] | [nm] |
| 972 | 0.066 |
| 675 | 0.057 |
| 405 | 0.063 |

Batch-Type CMP Process:

The present disclosure aqueous suspension S-I1 results in an excellent surface roughness of equal to or less than 3 Angstroms while the use of higher amounts of alumina particles (see comparative aqueous suspensions S-C1 to S-C3) results in significantly higher surface roughness and therefore reduced quality of the polished SiC substrate. Use of comparative aqueous suspensions S-C6 and S-C7 including ferric nitrate and cerium nitrate results in a high scratching of the substrate surface and provides polished products having an unacceptable quality. A surface roughness for comparative aqueous suspensions S-C5, S-C8 and S-C9 could not be determined due to their low stability after preparation (see Table 12 above).

Single-Type CMP Process:

The present disclosure aqueous suspension S-I1 allows to achieve an excellent surface roughness even at high down pressures and therefore allows a fast polishing process providing excellent yields.

5. Discussion of the Results

The present disclosure aqueous suspension S-I1 including less than 0.2 wt.-% alumina particles as well as aluminum nitrate results in high material removal rates as well as an excellent surface roughness in batch-type as well as single-type CMP processes. Moreover, these suspensions have an excellent storage stability of more than 12 month, thus ensuring a constant material removal rates and surface quality in the polishing process during their shelf life. Without wishing to be bound to this particular theory, the presence of aluminum nitrate seems to prevent or reduce a pH shift occurring during storage due to the dissolution of the alumina particles in the acidic media and moreover forms a “soft” layer on the alumina particles which allows to obtain polished products having a high surface quality (i.e. a low surface roughness). Surprisingly, high material removal rates are only achieved if an aqueous solution of oxidizing agent is added to an aqueous suspension including alumina particles and aluminum nitrate, while addition of an aqueous suspension of alumina particles and aluminum nitrate to an aqueous solution of potassium nitrate results in reduced material removal rates (see comparative suspension S-C5).

In contrast, aqueous suspensions including less than 0.2 wt.-% of alumina particles and other nitrates than aluminum nitrate (comparative suspensions S-C6 to S-C9) show a significantly reduced storage stability due to a pH drift occurring upon storage. This pH drift results in the formation of manganese dioxide, which reduces the material removal rates and significantly increases the surface roughness of the polished substrates.

Suspensions including 0.2 wt.-% to 1 wt.-% of alumina particles and aluminum nitrate (comparative suspensions S-C1 to S-C3) show a high storage stability and result in increased the material removal rates in batch-type CMP processes as compared to the suspension of the present disclosure. However, the increased material removal rates are associated with an unacceptable increase in the surface roughness of the polished substrate, thus drastically reducing the yield of the polishing process. Further increase of the amount of alumina particles to 5 wt.-% of resulted in unstable suspensions which do not have the required storage stability.

In conclusion, the present disclosure aqueous suspensions with less than 0.2 wt.-% of alumina particles as well as aluminum nitrate and which are prepared by the present disclosure process allow to achieve high material removal rates and an excellent surface roughness (i.e., a high yield) of the polished substrate in batch-type as well as single-type CMP processes. The high material removal rates render the polishing process more efficient because they allow to reduce the polishing time. Moreover, the present disclosure aqueous suspensions have an excellent storage stability, thus ensuring a constant quality in the CMP process during their shelf-life.

Aspects

Various Aspects are described below. It is to be understood that any one or more of the features recited in the following Aspect(s) can be combined with any one or more other Aspect(s).

Aspect 1. An aqueous suspension comprising: (a) one or more metal salts of permanganic acid; (b) zirconia nanoparticles; (c) alumina nanoparticles; and (d) one or more salts of nitric acid.

Aspect 2. The aqueous suspension of Aspect 1, further comprising at least one pH adjusting agent and/or at least one pH buffering agent.

Aspect 3. The aqueous suspension of Aspect 1 or 2, wherein the aqueous suspension has a pH value in a range from 2 to 5.

Aspect 4. The aqueous suspension of Aspect 3, wherein the pH value is measured at a temperature in a range of from 20° C. to 30° C.

Aspect 5. The aqueous suspension of Aspect 3, wherein the pH value is measured at a temperature of 23° C.

Aspect 6. The aqueous suspension as in any of the preceding Aspects, wherein the one or more metal salts of permanganic acid is selected from the group consisting of LiMnO₄, KMnO₄, NaMnO₄, and mixtures thereof.

Aspect 7. The aqueous suspension as in any of the preceding Aspects, wherein the zirconia nanoparticles comprise ZrO₂.

Aspect 8. The aqueous suspension as in any of the preceding Aspects, wherein the alumina nanoparticles comprise colloidal alumina particles.

Aspect 9. The aqueous suspension of Aspect 8, wherein the colloidal alumina particles comprise γ-AlOOH particles and/or γ-Al₂O₃ particles.

Aspect 10. The aqueous suspension as in any of the preceding Aspects, wherein the one or more salts of nitric acid comprises Al(NO₃)₃.

Aspect 11. The aqueous suspension as in any of the preceding Aspects, wherein the aqueous suspension is absent MnO₂.

Aspect 12. A method of chemically-mechanically planarizing a substrate, comprising: (i) contacting the substrate with an aqueous suspension of Aspect 1; (ii) moving the aqueous suspension with a polishing pad relative to the substrate; and (iii) abrading at least a portion of the substrate to polish the substrate.

Aspect 13. The method of Aspect 12, wherein the substrate is a silicon carbide substrate.

Aspect 14. The method of Aspect 12 or Aspect 13, wherein the substrate does not exceed a temperature of 60° C. during abrading.

Aspect 15. The method as in any of Aspects 12-14, further comprising, before contacting the substrate with the aqueous suspension, reducing a pH of the aqueous suspension to a range of 2 to 2.5.

Aspect 16. The method of Aspect 15, wherein the pH is reduced by adding an acid.

Aspect 17. The method of Aspect 15, wherein the substrate is contacted with the aqueous suspension within fourteen days of reducing the pH.

Aspect 18. A method for preparing an aqueous suspension, comprising: (i) adding aluminum nitrate to the aqueous suspension comprising alumina nanoparticles and zirconia nanoparticles; and (ii) adding an aqueous solution of one or more metal salts of permanganic acid to the aqueous suspension.

Aspect 19. The method of Aspect 18, further comprising, prior to the adding the aluminum nitrate, filtering the aqueous suspension.

Aspect 20. The method of Aspect 18 or Aspect 19, further comprising, prior to the adding the aqueous solution, filtering the aqueous solution of one or more metal salts of permanganic acid.

Aspect 21. The method as in any of the preceding Aspects, wherein the aqueous suspension is absent MnO₂.

Aspect 22. The method as in any of the preceding Aspects, wherein the aqueous suspension has a pH value in a range from 2 to 5 at 23° C.

Aspect 23. The method as in any of the preceding Aspects, wherein the step (i) and the step (ii) are sequentially carried out.

Aspect 24. A method comprising: storing an aqueous suspension having a pH ranging from 3 to 5; reducing the pH of the aqueous suspension to range from 2 to 2.5; and using the aqueous suspension having the pH ranging from 2 to 2.5 within fourteen days.

Aspect 25. The method of Aspect 24, wherein the aqueous suspension comprises: (a) one or more metal salts of permanganic acid; (b) zirconia nanoparticles; (c) alumina nanoparticles; and (d) one or more salts of nitric acid.

Aspect 26. The method of Aspect 24 or Aspect 25, wherein the aqueous suspension is stored for at least 1 year.

Aspect 27. The method as in any of the preceding Aspects, wherein the pH of the aqueous suspension is reduced by adding an acid, and wherein the acid comprises nitric acid.

Aspect 28. The method as in any of the preceding Aspects, wherein the pH of the aqueous suspension is reduced to 2.3.

Aspect 29. The method as in any of the preceding Aspects, wherein the aqueous suspension having the pH ranging from 2 to 2.5 is used in a single-type or batch-type chemical mechanical planarization method.

Aspect 1. An aqueous suspension comprising: (a) one or more metal salts of permanganic acid; (b) one or more kinds of zirconia nanoparticles; (c) one or more kinds of alumina nanoparticles; (d) one or more salts of nitric acid; (e) one or more kinds of calcined alumina particles; (f) one or more metal salts of chloric acid; and (g) one or more metal salts of perchloric acid.

Aspect 2. The aqueous suspension of Aspect 1, further comprising at least one pH adjusting agent and/or at least one pH buffering agent.

Aspect 3. The aqueous suspension of Aspect 1 or Aspect 2, wherein the aqueous suspension has a pH value in a range from 2 to 5.

Aspect 4. The aqueous suspension of Aspect 3, wherein the pH value is measured at a temperature in a range of from 15° C. to 40° C.

Aspect 5. The aqueous suspension of Aspect 3, wherein the pH value is measured at a temperature of 23° C.

Aspect 6. The aqueous suspension as in any of the preceding Aspects, wherein the one or more metal salts of permanganic acid is selected from the group consisting of LiMnO₄, KMnO₄, NaMnO₄, and mixtures thereof.

Aspect 7. The aqueous suspension as in any of the preceding Aspects, wherein the one or more kinds of zirconia nanoparticles comprise ZrO₂.

Aspect 8. The aqueous suspension as in any of the preceding Aspects, wherein the one or more kinds of alumina nanoparticles comprise colloidal alumina particles.

Aspect 9. The aqueous suspension of Aspect 8, wherein the colloidal alumina particles comprise γ-AlOOH particles and/or γ-Al₂O₃ particles.

Aspect 10. The aqueous suspension as in any of the preceding Aspects, wherein the one or more salts of nitric acid comprises Al(NO₃)₃.

Aspect 11. The aqueous suspension as in any of the preceding Aspects, wherein the one or more kinds of calcined alumina particles comprises aluminum oxide that has been heated at temperatures in excess of 1000° C. to drive off chemically combined water.

Aspect 12. The aqueous suspension as in any of the preceding Aspects, wherein the one or more metal salts of chloric acid comprises NaClO₃.

Aspect 13. The aqueous suspension as in any of the preceding Aspects, wherein the one or more metal salts of perchloric acid comprises Al(ClO₄)₃.

Aspect 14. The aqueous suspension as in any of the preceding Aspects, wherein the aqueous suspension is absent MnO₂.

Aspect 15. A method of chemically-mechanically planarizing a substrate, wherein the method comprises: (i) contacting the substrate with an aqueous suspension of claim 1; (ii) moving the aqueous suspension with a polishing pad relative to the substrate; and (iii) abrading at least a portion of the substrate to polish the substrate.

Aspect 16. The method of Aspect 15, wherein the substrate is a silicon carbide substrate.

Aspect 17. The method of Aspect 15 or Aspect 16, wherein the substrate does not exceed a temperature of 60° C. during abrading.

Aspect 18. The method as in any of the preceding Aspects, further comprising, before contacting the substrate with the aqueous suspension, reducing a pH of the aqueous suspension to a range of 2 to 2.5.

Aspect 19. The method of Aspect 18, wherein the pH is reduced by adding an acid.

Aspect 20. The method of Aspect 18, wherein the substrate is contacted with the aqueous suspension within fourteen days of reducing the pH.

Aspect 21. A method for preparing an aqueous suspension, comprising: (i) adding aluminum nitrate to the aqueous suspension comprising alumina nanoparticles and zirconia nanoparticles; (ii) adding an aqueous solution of one or more metal salts of permanganic acid, one or more metal salts of perchloric acid, and one or more metal salts of chloric acid to the aqueous suspension; and (iii) adding one or more kinds of calcined alumina particles to the aqueous suspension.

Aspect 22. The method of Aspect 21, further comprising, prior to adding the aluminum nitrate, filtering the aqueous suspension.

Aspect 23. The method of Aspect 21 or Aspect 22, further comprising, prior to adding the aqueous solution, filtering the aqueous solution.

Aspect 24. The method as in any of the preceding Aspects, wherein the aqueous suspension is absent MnO₂.

Aspect 25. The method as in any of the preceding Aspects, wherein the aqueous suspension has a pH value in a range from 2 to 5 at 23° C.

Aspect 26. The method as in any of the preceding Aspects, wherein the step (i), the step (ii), and the step (iii) are sequentially carried out.

Aspect 27. A method comprising: storing an aqueous suspension having a pH ranging from 3 to 5; reducing the pH of the aqueous suspension to range from 2 to 2.5; and using the aqueous suspension having the pH ranging from 2 to 2.5 within fourteen days.

Aspect 28. The method of Aspect 27, wherein the aqueous suspension comprises: (a) one or more metal salts of permanganic acid; (b) one or more kinds of zirconia nanoparticles; (c) one or more kinds of alumina nanoparticles; (d) one or more salts of nitric acid; (e) one or more kinds of calcined alumina particles; (f) one or more metal salts of chloric acid; and (g) one or more metal salts of perchloric acid.

Aspect 29. The method of Aspect 27 or Aspect 28, wherein the aqueous suspension is stored for at least 1 year.

Aspect 30. The method as in any of the preceding Aspects, wherein the pH of the aqueous suspension is reduced by adding an acid, and wherein the acid comprises nitric acid.

Aspect 31. The method as in any of the preceding Aspects, wherein the pH of the aqueous suspension is reduced to 2.3.

Aspect 32. The method as in any of the preceding Aspects, wherein the aqueous suspension having the pH ranging from 2 to 2.5 is used in a single-type or a batch-type chemical mechanical planarization method.

Aspect 1. An aqueous suspension comprising: at least one oxidizing agent; a total amount of less than 0.2 wt.-% of abrasive particles based on a total weight of the aqueous suspension, wherein the abrasive particles have a Mohs hardness of less than 6; and aluminum nitrate.

Aspect 2. The aqueous suspension of Aspect 1, further comprising at least one pH adjusting agent and/or at least one pH buffering agent.

Aspect 3. The aqueous suspension of Aspect 1 or Aspect 2, wherein the aqueous suspension has a pH value in a range from 2 to 5.

Aspect 4. The aqueous suspension of Aspect 3, wherein the pH value is measured at a temperature in a range of from 15° C. to 40° C.

Aspect 5. The aqueous suspension of Aspect 3, wherein the pH value is measured at a temperature of 23° C.

Aspect 6. The aqueous suspension as in any of the preceding Aspects, wherein the at least one oxidizing agent is selected from the group consisting of LiMnO₄, KMnO₄, NaMnO₄, and mixtures thereof.

Aspect 7. The aqueous suspension of Aspect 6, wherein the at least one oxidizing agent is KMnO₄.

Aspect 8. The aqueous suspension as in any of the preceding Aspects, wherein the abrasive particles comprise alumina particles.

Aspect 9. The aqueous suspension of Aspect 8, wherein the alumina particles comprise γ-AlOOH particles.

Aspect 10. The aqueous suspension of Aspect 8, wherein the alumina particles are γ-AlOOH particles.

Aspect 11. The aqueous suspension as in any of the preceding Aspects, wherein the aqueous suspension is absent MnO₂.

Aspect 12. A method of chemically-mechanically planarizing a substrate, comprising: (i) contacting the substrate with an aqueous suspension of claim 1; (ii) moving the aqueous suspension with a polishing pad relative to the substrate; and (iii) abrading at least a portion of the substrate to polish the substrate.

Aspect 13. The method of Aspect 12, wherein the substrate comprises at least one layer of silicon carbide.

Aspect 14. The method of Aspect 13, wherein the at least one layer of silicon carbide is at least one layer of single crystal silicon carbide.

Aspect 15. The method as in any of the preceding Aspects, wherein the substrate does not exceed a temperature of 60° C. during abrading.

Aspect 16. The method as in any of the preceding Aspects, further comprising, before contacting the substrate with the aqueous suspension, reducing a pH of the aqueous suspension to a range of 2 to 2.5.

Aspect 17. The method of Aspect 16, wherein the pH of the aqueous suspension is reduced by adding an acid.

Aspect 18. The method Aspect 16, wherein the substrate is contacted with the aqueous suspension within fourteen days of reducing the pH.

Aspect 19. A method for preparing an aqueous suspension, comprising: (i) adding aluminum nitrate to the aqueous suspension comprising abrasive particles; and (ii) adding an aqueous solution of at least one oxidizing agent to the aqueous suspension, wherein the abrasive particles have a Mohs hardness of less than 6, and wherein the aqueous suspension contains less than 0.2 wt.-% of the abrasive particles based on a total weight of the aqueous suspension.

Aspect 20. The method of Aspect 19, further comprising, prior to adding the aluminum nitrate, filtering the aqueous suspension.

Aspect 21. The method of Aspect 19 or Aspect 20, further comprising, prior to adding the aqueous solution, filtering the aqueous solution.

Aspect 22. The method as in any of the preceding Aspects, wherein the aqueous suspension is absent MnO₂.

Aspect 23. The method as in any of the preceding Aspects, wherein the aqueous suspension has a pH value in a range from 2 to 5 at 23° C.

Aspect 24. The method as in any of the preceding Aspects, wherein the step (i) and the step (ii) are sequentially carried out.

Aspect 25. A method comprising: storing an aqueous suspension having a pH ranging from 3 to 5; reducing the pH of the aqueous suspension to range from 2 to 2.5; and using the aqueous suspension having the pH ranging from 2 to 2.5 within fourteen days.

Aspect 26. The method of Aspect 25, wherein the aqueous suspension comprises: at least one oxidizing agent; a total amount of less than 0.2 wt.-% of abrasive particles based on a total weight of the aqueous suspension, wherein the abrasive particles have a Mohs hardness of less than 6; and aluminum nitrate.

Aspect 29. The method of Aspect 25 or Aspect 26, wherein the aqueous suspension is stored for at least 1 year.

Aspect 29. The method as in any of the preceding Aspects, wherein the pH of the aqueous suspension is reduced by adding an acid, and wherein the acid comprises nitric acid.

Aspect 30. The method as in any of the preceding Aspects, wherein the pH of the aqueous suspension is reduced to 2.3.

Aspect 31. The method as in any of the preceding Aspects, wherein the aqueous suspension having the pH ranging from 2 to 2.5 is used in a single-type or batch-type chemical mechanical planarization method.

Aspect 32. The method as in any of the preceding Aspects, wherein using the aqueous suspension comprises using the aqueous suspension having the pH ranging from 2 to 2.5 is used in a batch-type chemical mechanical planarization method.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. An aqueous suspension comprising:
(a) one or more metal salts of permanganic acid;
(b) zirconia nanoparticles;
(c) alumina nanoparticles; and
(d) one or more salts of nitric acid.

2. The aqueous suspension of claim 1, further comprising at least one pH adjusting agent and/or at least one pH buffering agent.

3. The aqueous suspension of claim 1, wherein the aqueous suspension has a pH value in a range from 2 to 5.

4. The aqueous suspension of claim 1, wherein the one or more metal salts of permanganic acid is selected from the group consisting of LiMnO₄, KMnO₄, NaMnO₄, and mixtures thereof.

5. The aqueous suspension of claim 1, wherein the zirconia nanoparticles comprise ZrO₂.

6. The aqueous suspension of claim 1, wherein the alumina nanoparticles comprise colloidal alumina particles.

7. The aqueous suspension of claim 6, wherein the colloidal alumina particles comprise γ-AlOOH particles and/or γ-Al₂O₃ particles.

8. The aqueous suspension of claim 1, wherein the one or more salts of nitric acid comprises Al(NO₃)₃.

9. A method of chemically-mechanically planarizing a substrate, comprising:
(i) contacting the substrate with an aqueous suspension of claim 1;
(ii) moving the aqueous suspension with a polishing pad relative to the substrate; and
(iii) abrading at least a portion of the substrate to polish the substrate.

10. The method of claim 9, wherein the substrate does not exceed a temperature of 60° C. during abrading.

11. The method of claim 9, further comprising, before contacting the substrate with the aqueous suspension, reducing a pH of the aqueous suspension to a range of 2 to 2.5.

12. A method for preparing an aqueous suspension, comprising:
(i) adding aluminum nitrate to the aqueous suspension comprising alumina nanoparticles and zirconia nanoparticles; and
(ii) adding an aqueous solution of one or more metal salts of permanganic acid to the aqueous suspension.

13. The method of claim 12, further comprising, prior to the adding the aluminum nitrate, filtering the aqueous suspension.

14. The method of claim 12, further comprising, prior to the adding the aqueous solution, filtering the aqueous solution of one or more metal salts of permanganic acid.

15. The method of claim 12, wherein the aqueous suspension has a pH value in a range from 2 to 5 at 23° C.

16. The method of claim 12, wherein the step (i) and the step (ii) are sequentially carried out.
